(19) United States
(12) Patent Application Publication
(10) Pub. No.: US 2025/0348642 A1
(43) Pub. Date: Nov. 13, 2025

(54) CONTENT COMPUTE PROCESSORS AND ARCHITECTURES

(71) Applicant: Raminda U. Madurawe, Sunnyvale, CA (US)

(72) Inventor: Raminda U. Madurawe, Sunnyvale, CA (US)

(21) Appl. No.: 18/656,851

(22) Filed: May 7, 2024

(51) Int. Cl. G06F 30/327; G06F 30/323; G06F 30/392

(52) U.S. Cl. CPC G06F 30/327; G06F 30/323; G06F 30/392

(57) ABSTRACT

Software tools, tools flows and software infrastructure to extract content and execute extracted content in hardware (termed content-computing) from a high-level language description of an application software program is disclosed. A software program for content-computing comprises: a high-level logic synthesis software to convert an identified content in an application program to a synthesized hardware image; and a language compiler software to instantiate the content customized instruction to execute in a configurable hardware unit programmed to the synthesized hardware image. A software tools flow to generate executable instructions in an application software program comprises a combined high level logic synthesis software and language compiler software to: identify an application software program content that is targeted for hardware implementation as a hardware function in a configurable hardware unit that comprises configuration memory; generate a synthesized gate-level netlist of the targeted hardware function; generate a bit-stream of configuration memory to program the targeted hardware function in the configurable hardware unit; and generate a compiled hardware instruction for a processor unit to execute the instruction in the configured hardware function.

This application claims priority from Provisional Application Ser. No. 63/468,059 entitled “Macro-Processor Architectures”, filed on 22-May-2023 and Provisional Application Ser. No. 63/468,061 entitled “Content-Compute Processors and Architectures”, filed on 22-May-2023, all of which have as inventor Mr. Raminda U. Madurawe and the contents of which are incorporated-by-reference.

This application is related to application Ser. No. 18/656,824 entitled “Content Macroprocessor Architectures for Pipelined Flexible-Function Computing” and application Ser. No. 18/656,836 entitled “Interconnect Structures for Configurable CPU Pipelines”, both filed concurrently and list as inventor Mr. Raminda U. Madurawe, the contents of which are incorporated-by-reference.

### BACKGROUND

### 1. Field of the Invention

The present invention relates to integrated circuits (IC), and to computer processor units (CPU), field programable gate arrays (FPGA) and application specific integrated circuits (ASIC). CPUs includes microprocessors, microcontrollers and other forms of instruction-based processing units. Integrated circuits require electronic design automation (EDA) software tools to design ICs, and application software to use ICs. Software tools and tool flows convert user application software to IC executable code. Software infrastructure provides the framework to manage application software and generate execution code in ICs. The invention is also related to software tools and tool flows, software infrastructure, software architecture and software-hardware interactions that enable user application content to efficiently execute (content computing) in CPUs and ICs.

### 2. Prior Art

A Microprocessor, also known as a Central Processing Unit (CPU), is a widely used instruction processing device in the Integrated Circuits industry. It comprises a plurality of pre-defined hardware functions of a hardware architecture (HWA) that match to an instruction set architecture (ISA). Each instruction identifies a plurality of dedicated hardware functions, including data transfer events, data execute instruction. All Microprocessors follow von-Neumann, or modified Harvard data-path/control-path architectures. Microprocessor data can be classified into two groups: (i) instruction data, telling the computer what to do and (ii) compute data, the information needed to execute each instruction. An external memory unit, such as a Solid-State Drive (SSD), stores computer boot code, compute data and program instruction in different segments of the memory. A CPU comprises a data unit (memory, I-cache, D-cache) and a control unit. In this disclosure a Harvard architecture where instruction and data buses are separated is used in illustrations. The control unit generates all hardware signals (level signals, pulse signals, hard-ware control signals, data transfers, etc.) for accurate instruction execution through its entire time of flight in pre-defined hardware structures. It also ensures continuity of instruction flow. Control unit interacts with external systems (external to CPU in an SoC) such as the operating system (OS), memory management units (MMU), and thermal management units, etc. The two biggest disadvantages in the CPU are: von-Neuman instruction bottleneck (leading to poor compute data throughput and low instructions per cycle IPC), and use of pre-defined HW structures that must adhere to a small set of ISA-instructions (lack of flexibility, poor performance and high-power consumption).

Matching ISA-HWA duality allows defining a set of micro-code that map to hardware. A compiler takes a high-level language SW application program and convert it to micro-code using this mapping. Control-unit orchestrates the micro-code (aka assembly code, micro-instructions, instructions) execution, each micro-code having multiple sub-tasks to perform. It takes a few cycles, known as latency, to complete a task. The control-unit knows the latency of every sub-task since HW is pre-defined. A program-counter in the control-unit facilitates loading of the next instruction. Tags link instructions and related data in the CPU. Instructions are fetched from I-cache to an instruction queue in a CPU-pipeline. A CPU-pipeline is a sequence of HW operations needed to complete execution of all instructions. In the CPU-pipeline, decode informs the control-unit sub-tasks needed. CPU-pipeline contains ISA-compatible pre-defined hardware-units to perform computation-tasks that can modify data, such as: arithmetic logic units (ALU), floating-point units (FPU), address generation unit (AGU, branch prediction & program counter unit (BRU), Integer-Math Unit (IMU). Collectively, they are called execution-units. Each execution unit has a plurality of selectable pre-defined sub-functions (an FPU has add, multiply, divide, etc.). Control unit engages a Load/Store unit to transfer compute data between D-cache and a chosen hardware execution unit. In a RiscV CPU-pipeline, there is a common shared 32-word General-Purpose Register (GPR) between D-cache & all execution-units. In a 4-wide super-scalar (4 branches per CPU-pipeline), with 2-threads (2 CPU-pipelines), as least 8 execution-units share the same 32-word GPR. Sharing allows HWA complexity manageable. Some branches in a CPU-pipelines may have more than one execution unit, in which case more than 8 execution units share the GPRs. All control-unit selections are via an N-bit control-signal (from a look-up-table, or a micro-controller), where N is an integer between 4 & 12. N=12 would need 2¹²=4096 wires, which is very large and difficult to distribute, area gets bloated and expensive, and timing gets slow. Control unit selectable pre-defined hardware components limit the flexibility desired by software coders, especially for bigdata, blockchain, AI and LLM applications. Sharing GPRs limit the instructions per cycle (IPC) of the CPU. Compilers can only assemble the pre-defined set of hardware micro-code, to translate the user SW application to executable code. This is inefficient. Integrating a new HW-feature into a compiler (new micro-code) is significantly costly and time consuming. Deviating from a known standard architecture, such as X86, RiscV and ARM, comes at a significant penalty to software tools and ease of user adoption.

System on Chip (SoC) designs include HW content based on register-transfer logic (RTL) design. Hardware design requires Verilog or RTL coding. High level language applications must be recoded if a hardware function is needed, a skill the application developer does not possess. RTL defined logic functions use standard cell (or gate array) logic gates, simulated using CAE-tools to ensure functionality and timing accuracy, and synthesized to a gate-level netlist. A synthesis tool is required. Embedded ASICs in an SoC uses a standard cell library, is a custom HW block, and it communicates with the CPU using a communication-BUS (such as AMBA bus). An embedded ASIC can exceed millions of logic gates, such as a Huffman coder/decoder for data compression, can eliminate thousands of lines of micro-code, and frequently used as accelerators. However, even if the Accelerator is tightly coupled to the CPU over a communication-BUS, the ISA must be modified (ISA-extension), CSRs must be invoked (data transfer delays) and memory-management must be modified. It is impractical to provide 100 s of embedded ASICs for general purpose computing for application-specific user to pick one or two applicable for them. They are not flexible, and gets obsoleted quickly. In fact, ALUs, FPUs are a few common hardware components (least common denominator) that have survived over time. Vector-Units (radix2, radix4, int4, int8, fp8, fp16 choices) & NPUs (convolution vs. transformers) get outdated quickly. Microprocessor ISA's offer off-chip third party accelerator interfaces to avoid these pitfalls, those interfaces must use loosely-coupled bus-communication protocols that make data transfer penalties tremendous, in addition to software application edits needed to code the partitioned hardware interfaces.

Not all instructions are related to data-compute. Many are related to data-movement (such as load, store, move etc.) and some are related to tracking and book-keeping (such as stack pointer, program counter, jump etc.). Inside the CPU-pipeline, instructions move through pipeline-stages. In modern CPUs there may be 7, 20 or 30 such stages (each stage forming a sub-task of an instruction). Stages are bounded by register-files, instruction movement is serial. Instruction registers (IR) hold instruction data. The IR-Opcode defines all available micro-instructions. In RISC, the smaller IR-Opcode uses a fewer, simpler set of instructions. A complex command is divided into simpler instructions. Smaller IR-Opcode, requires less RAM in storage and Instruction Registers, less power to move instructions, making CPU-pipelines more efficient and simpler to build. It comes with increase compiled code density penalty. A CISC uses a higher IR-Opcode, has a larger ISA, has less source-code density as complex tasks take up fewer lines to code. Processor hardware is more complex, takes up more area, consumes more power. Some operations in CISC may require one instruction, while it requires 4 instructions in RISC. Low code size in CISC does not necessarily reduce Cycles Per Instruction (CPI) as more cycles may be needed to complete the complex instruction. CPUs struggle with this trade-off: simplify coding with CISC, use complex HWA, have less compiled code to store; or simplify HWA with RISC, have more compile code to store. Best of both worlds do not exist due to HWA complexity and mesh (wires & buses) requirements.

The single most advantage of general-purpose microprocessor is in the ability for a user to write very high-level software programs in languages such as Python, Java, C++, etc. and have that code compile into the ISA and HWA via software preprocessors, compilers, assemblers, linkers and loaders. This has led to the electronic universe as we know today, with a proliferation of software applications that use microprocessor-based computers (CPUs).

A first disadvantage is that a CPU must receive Instruction-Data as well as Compute-Data. Inside the CPU IC-chip, Input-Output (IO) interfaces determine total data bandwidth available. It is widely documented in the literature that IC-chip computing is IO-bandwidth limited. IO-Bandwidth scaling ˜½ the rate of transistor scaling (Ref-1) defined by Moore's law exacerbating the problem over time. CISC/RISC architecture do not resolve the diminishing IO-bandwidth limitation. This is a major drawback to Big-Data and High-Performance-Computing application needs. We need higher IO-bandwidth for compute-data.

A second disadvantage to Microprocessor computing is the amount of wasted power needed to move instructions on a cycle-by-cycle basis, every cycle. In a 4-wide, 2-thread, 30-stage CPU-pipeline, we need 4×2×30=240 instruction movements to get 6-execute (IPC=3) operations. A rule of thumb estimate in microprocessor super-scalars power consumption, is that only ˜10% of the CPU-core power is used up by the execute-unit; remaining 90% is used up by the instruction movement and logistics in an out-of-order (OOO) instruction processor. For a 4 GHz clock frequency, there are 960 B (B=billion) power consuming operations/sec to realize 24 B useful computes. We need the power consumption dedicated to useful data compute activity, not to move instructions around.

A third disadvantage to Microprocessor computing is its inability to process sequential compute operations. A SIMD operation must share the same instruction, a CPU does not allow crossing work-loads across threads. If a compiler can compile micro-code to use super-scalar width for SIMD, a 4-wide superscalar can achieve 4 SIMD operations in parallel. This number is severely marginalized by the shared GPR depth, 32-words in RiscV. Highly parallel SIMD has excellent value in certain operations like matrix-multiplication, but 4 or 8 SIMD is not adequate. Transformers need 1000's of multiply-accumulate (MAC) operations in parallel. More often, the output of a compute function becomes an input to the next compute function, a sequential feature seen in cryptography, security, multi-media, enterprise search engines & AI. Often times compute data is encrypted, encoded and compressed, and transmitted in variable length packets. CPUs cannot pipeline data-operations when pre-defined hardware is not structured to do so. CPUs would benefit by complex function execution, where the function may be dynamically altered to fit the application need.

Microprocessor ISA and HWA do not lend to compute data pipelining of random order in HW functions based on user application instruction order. In super-scalars, the GPR physical addresses are dedicated to execution-units, its output result has to be written back to that address space. To be used by another execution unit, that output must be moved to the new address space. In the HWA, some selected pipelined stages may offer pre-designed by-pass capability, the HW choice useful only if the compiler made use of it during compile-code optimization. These inefficiencies, coupled with data-dependency, cache-misses and branch-prediction misses limit the Instructions-Per-Cycle (IPC) metric. For best-in-class RiscV super-scalars this IPC˜3 regardless of super-scalars designed with 16 parallel execution-units in the CPU-pipeline. A fourth disadvantage in microprocessors is the low IPC. number in spite of increasing available HW resources significantly. IPC<3 seen in Spec2K performance bench-marks indicate that user programs do not lend easily to parallel HW utilization in general purpose computing. It is desirable to improve the CPU IPC metric for general computing.

Microprocessor ISA does not allow Application-Specific Software performance optimization. Application SW developers use algorithms and diagrams to conceptualize their requirements, use high-level language code to write the SW program, then compile the SW-program to executable assembly code to execute the application context. A “potential” ASIC function in application-SW gets compiled to generic assembly code, sacrificing performance and power for compile convenience. Two options available to improve are: redesign a new IC with accelerators, or use an external 3^{rd} party accelerator, both expensive, time consuming, needing re-coding of application SW, and may even need a new compiler. A Graphic Processor Unit (GPU) is an example of a highly SIMD vector-unit, useful for a few applications. Other attempts use neural processor units (NPU), language processor units (LPU), in-memory compute units (IMC), etc. Those need custom compilers & can get obsolete very quickly. Applications change regularly, AI-LLMs evolve continuously. Embedded systems need CPU to handle generic code. Contrasting features in GPU, RISC, CISC, embedded-cores are all needed by the users. We need SIMD/MIMD computing in RISC/CISC instructions, we need SIMD/MIMD capability in GPUs, and we need flexible NPU/LPU/IMC capability in hardware. This is another disadvantage with Microprocessor architectures: not getting optimal and efficient hardware for application-specific software APIs. We want these hardware features, without having to re-invent the user interface, SW tools & infrastructure, tools flow, and user-APIs needed to execute SW in HW.

A Field Programmable Gate Array (FPGA) is a widely used second embodiment of a general-purpose programmable device in the Integrated Circuits industry. An FPGA tile comprises an array of programmable blocks, programmable interconnects, configuration and storage memory, digital signal processing (DSP) HW blocks, and switch-blocks. A plurality of replicated tiles together with IO and other circuitry forms the FPGA chip. A user programmable logic block comprises one or more programmable logic elements and configurable connection switches. A programmable logic element further comprises one or more programmable look up table functions (known as LUTs) and one or more distributed registers embedded within the logic element. A LUT-function can implement any user logic function of N-inputs. As an example, a 4-input LUT function (termed 4LUT) has 16 Memory-Cells to store the LUT values. Any combination of 4 inputs (0, 1 combinations) will select one of those 16 LUT-values. An 8-input LUT function would require 2⁸×256 configurable LUT-values to implement all possible functions. A LUT-tree is when an 8-input function is broken into 4-input LUT-functions, and concatenated to complete the 8-input function. In a LUT-tree, 16 4LUTs with 4 common inputs would feed into a 4LUT that receive the remaining 4-inputs, to build the 8-input LUT tree. A truth-table can be constructed to represent the desired function, and the 16 memory bits in 4LUT programmed to implement the desired function. A software tool does this translation easily. A LUT is a bit-wise operation. Operands or data is received as inputs to LUTs. LUT function is programmed as LUT-values. Outputs of LUT functions can be registered, or connected as inputs to an adjacent LUT function in same logic block, or in a different logic block, using the programmable routing connections. Complex combinational or sequential logic trees can be constructed to implement very large designs. As an example, an entire RISC microprocessor core can be implemented in an FPGA fabric. Switch-blocks assist in the connectivity of horizontal and vertical wires in an FPGA interconnect structure. The interconnects are programmed by a software tool that extracts logic connectivity from a synthesized netlist of a design. Memory and DSP HW blocks provide data storage and accelerated math-functions in an FPGA. These are important features to get higher performance. The LUT functions offer special carry-in and carry-out signals to facilitate carry-logic implementations using LUTs. LUTs also offer logic needed to convert integer numbers to floating-point numbers for arithmetic operations. Configurability allows the user to program the FPGA to execute very complex user specific applications. Configurability makes FPGAs a general-purpose IC device that is customizable to a user specification.

Inputs to LUT-functions, LUT-function grouping, register density, logic element-block-tile hierarchy, interconnect hierarchy, interconnect and switch density, all play into incrementally building larger and more complex combinational and sequential logic functions to realize good compute performance and utilization efficiency at lower power consumption. To place a user application into a pre-fabricated FPGA, the user has to write the application in Verilog or RTL code, use a synthesis tool to convert RTL into a netlist of gates and nets. The synthesized netlist must be mapped into the FPGA HWA to pack LUTs, group LUTs in blocks, clusters, and tiles hierarchically, and route the nets to get the connectivity needed. A SW tool, called a Software Development Kit (SDK), automatically adjust LUT placement to get best timing for critical paths to operate at maximum frequency. It is common to see 16-levels of logic in a critical path that force maximum operational clock frequency to be about 200-500 MHz. The SW tool performs a timing & utilization analysis and ensure uniform logic placement with no setup or hold violations in the ensuing netlist connections. When a best-in-class Microprocessor can run at a clock frequency of ˜4 GHz, the best-in-class FPGA can only run at ˜400 MHz (10× slower). Once the application placement is finalized to user satisfaction, the pack-place & route (PPR) software tool sends out a Bit-Stream that define the status of every single configurable bit (called configuration memory, or CRAM bits) in the FPGA. Modern FPGAs use a custom SRAM cell to construct CRAM. A boot-ROM can hold this Bit-Stream (aka bit pattern), and at boot time, after the FPGA is powered up, the chip is configured using special circuits that perform this configuration of CRAM bits. It can take millions of cycles to completely configure the entire FPGA due to the sheer magnitude of total configuration CRAM bits resident in an FPGA. Since it is done only once during power up, the boot-time penalty is only incremental, with minimum impact to users. The term Bit-Stream is used herein to identify the bit level connectivity of FPGAs for a user defined function. After configuration, the FPGA acts as an ASIC until the Bit-Stream is changed to define a new function (or a new ASIC).

A single biggest advantage of FPGAs is that it can use pipelining and model-parallelism to improve compute-performance. Pipelining allows staging of sequential operations so that different tiles can work on parallel computes to increase the net compute efficiency. This is a MIMD operation: multiple-inputs, multiple-data. A 4-stage pipelining will not alter the latency of each Data-Compute delay from start to finish; but it will allow 4× faster data throughput since the 4 segments can simultaneously work on 4 consecutive data packets. Model parallelism allows instantiating multiple copies to parallelize data compute. This is better than the SIMD concept in microprocessors, since the user chooses level of MIMD data parallelism. Even discounting for the 10× slower FPGA performance, very high parallelization can offer a significant improvement in net compute performance, and FPGAs are often used as general-purpose data-accelerators. Due to 10× slower performance, high LUT logic & interconnect area requirement in bit-programmable FPGA fabrics, and the complexity involved in re-writing SW-code in Verilog or RTL, FPGAs are not easy to use as custom accelerators for domain specific applications.

A first and major disadvantage with an FPGA is that it is not a high-level SW code usable HW execution platform. SW code does not have Register-Transfer information, which is required by FPGA tools for HW implementation. Microprocessors operated on cyclical HWA that allows SW code to be easily translated to HW. All the vast collection of sophisticated SW applications that make up our universe, find no applicability to FPGA devices. Only a very small user-group can code in Verilog or RTL, and they lack the vast skill sets needed to convert the multitude of application-specific software platforms or APIs to RTL. Only a few applications are targeted to FPGA devices, and when that happens, the entire end-to-end application must reside inside the FPGA device to realize any benefit. It is desirable for FPGAs to contain a mechanism similar to “cyclical accuracy” in CPUs for software users code to execute in FPGAs more easily.

A second disadvantage with an FPGA that is related to the first disadvantage is that when synthesized RTL is placed and routed into critical-path logic trees, the overall compute performance & latency becomes a case-by-case output result of the gate-level netlist placement & optimization in the FPGA. Software tools cannot work with this uncertainty, as there is no mechanism to automatically pipeline sequential operations, or use model-parallelism to achieve a desired performance level. Data transfer from a host CPU into an FPGA accelerator is a performance bottleneck, since the CPU must rely on an IO-communication protocol to engage the FPGA. It is desirable to have SW tools determine how the FPGA logic placement and performance optimization, with a predictable latency that is tied to the CPU frequency, so that SW code can be pipelined in HW between the CPU and Accelerator. Such fabrics will facilitate heterogeneous computing across all HWA platforms (such as CPU & GPU) that depend on SW operability.

A third disadvantage with an FPGA is that the configuration area overhead to configure LUT logic and Routing is very high. It could be as high as 20%-33% of the Logic-Block area. This makes it slow & expensive to use FPGA's: slow since signals must traverse over the configuration area (larger capacitance & wire delay) and expensive due to silicon area penalty (compared to an ASIC). Reducing configuration bit CRAM density hurt logic placement & routing efficiency leading to poor utilization and poor performance. This has been proven in the FPGA industry by FPGA-venders who offer low cost, low performance products and high cost, high performance products by modifying CRAM bit density and interconnect/routing density. The total number of segmented wires needed in the configurable interconnect fabric is the biggest contributor to logic utilization inefficiency. It is desirable to have higher performance in an economical (lower configuration overhead area & cost) FPGA interconnect fabric.

A fourth disadvantage with an FPGA is that configuration time is very long for an application that may benefit from run-time dynamic configuration. There are two fundamental difficulties with dynamic reconfigurability of FPGAs. The first problem is the sheer number of configuration bits that must be loaded: these add up to millions to 100's of millions. It takes a long time to send this data from a Boot-ROM into distributed configuration CRAM bit locations. The second problem is a more disastrous driver-contention that can arise during bit-reconfiguration. Segmented wires when connected provide directionality for data movement, which is dictated by drivers. One end of the wire transmits the signal, and the other end receives the signal. Configuration bits at either end determine the driver side & receiver side: if incorrectly assigned, both ends of the wire segment can become drivers. This could happen during the CRAM bit configuration time as it occurs in segments. Contention cause wire segment to sink excessive power one driver attempts to drive wire segment to power rail, and the other attempts to drive it to ground rail. With millions of wire-segments, this power increase can be disastrous. In the best case, it could be a metal electromigration reliability problem as wire-segments are not designed to have static power dissipation for extended times. Under worst condition this could lead to damage (burnt metal) as high fan-out signals may have a plurality of conflicting drivers forcing power into one individual wire segments (or an individual via) that is the weak point in the net. It is desirable that we can dynamically and safely alter the functionality of the FPGA, so the user can make use of dynamically reconfigurable functions to maximize area utilization and compute efficiency.

Another disadvantage with an FPGA is that we must use an extra special circuit to reuse a specific logic function in time multiplexing when needed. To do so, the original design must be modified. An FPGA design is hard-wired in time domain like an ASIC. Input data arrive at input terminals, output data is generated at output terminals after a specified latency. If the same feature is needed twice by the same data, a first option is hard-code it twice in the data path. A second option is to custom build (insert) a controller loop into the code, and re-design the data path RTL for a repeat operation of the same function, inserting an intermediate data storage to facilitate reuse. Software algorithm developer simply specify a loop in SW code. There is no run-time decision to make that duplication in RTL. RTL goes thru logic synthesis and PPR-software to map a design into HW, whereas CPUs used a compiler to map user-code into HW. An example is when a user needs to add 16-bit numbers N-times, where N could be a variable: 8, 16, 32, 64. In a CPU we could use one 16-bit adder, and loop the adder in time domain 8 to 64 times by passing N thru the stack as a variable. In FPGA we could dedicate a maximum N=64 16-bit add loop as hard-wired logic, use padded dummy ‘0’ adds when N<64 into FPGA logic function. Adding extra control for loop back is at unnecessary area/cost penalty. What is desirable is to reuse FPGA logic functions “easily” when needed to improve area utilization and cost without having to re-engineer or modify the RTL-design. What is even more desirable is to mix and match FPGA functions to build more complex Macro-Functions along the lines of Microprocessor HW-reuse of simple instructions to build complex instructions.

Entry to hardware is through software. We need a novel software tools infrastructure tightly coupled with hardware architecture (HWA) that can overcome the above listed CPU and FPGA limitations. Novel SW infrastructure should work within the existing industry standard infrastructure to leverage the vast design community knowledge and experience in using standard tools. Any change must appear transparent to the user, such as using new drivers to use different hardware that appear transparent to users. Any novel software and hardware architectures that can overcome the von-Neuman or Harvard instruction processing bottleneck in CPUs needs to have a user-friendly, easy to deploy, software orchestration-layer that contains the augmentations without demanding user intervention. We need an integrated SWA-HWA combination that acts like a software-ASIC: you write software, and get the best-fit hardware. We need software tools and tools flows that generate the software-ASIC using high-level language application software transparent to the user.

### SUMMARY

A macroprocessor is an integrated circuit that has features, and capabilities that exceed microprocessors. It provides features and capabilities of ASICs, microprocessors (aka CPUs) and FPGAs, via configurable CPU-pipelines. A macroprocessor is a Multiple Instruction, Multiple Data (MIMD) compute unit that can significantly increase the number of computes per unit area and reduce net compute power. Said features include: hardware architecture, firmware, instructions, hardware resources & configurations. Said capabilities include: performance, power, price, quality and reliability, CPI & other metrics used in IC comparisons. A macroprocessor comprises configurable CPU-pipelines so that a user defined functions can be programmed, and dynamically altered, in hardware execution units within the CPU-pipeline. A macroprocessor adheres to ease of high-level software execution in heterogeneous hardware units. A macroprocessor facilitates content-computing.

Microprocessor features include an ISA & HWA of: a custom processor, ARM processor, x86 processor, MIPS processor, and RISC processor. The microprocessor may comprise one or more of: memory units, registers, arithmetic logic units (ALU), floating point units (FPU), address generation units (AGU), branch units (BRU), shifters, comparators, multipliers, integer processing units, digital signal processors (DSP), Analog Circuits, clocks, phase-lock-loops (PLL) and other circuits found in CPU circuits. FPGA features include: memory units, registers, ALUs, FPUs, carry-logic units, shifters, configurable logic elements, configurable memory (CRAM), look-up table logic blocks (LUT), comparators, multipliers, DSPs, Analog Circuits, clocks, PLLs, control status registers (CSR), configurable segmented interconnects and other circuits found in FPGA devices. ASIC features may comprise specific custom functions that are specifically designed to do complex functions, including hard-IP, soft-IP & Programmable-IP that can be integrated into chip design, including accelerator circuits that enhance compute performance. Memory includes any form of volatile or non-volatile memory elements, including: SRAM, flash, EEPROM, MRAM, eFuse, laser-fuse, OTP, RRAM, DRAM and state-transition memory. Memory includes cache.

A content compute processor facilitates content computing by extracting compute-content from a high-level language application program, and targets the content for custom hardware execution. An example of content-computing is hardware-accelerators, where a specific block of compute-code is separated and executed in an accelerator hardware. Embodiments of macroprocessor architecture and IC structures are provided in incorporated by reference application. Ser. No. 18/656,824 titled “Microprocessor Architectures for Pipelined Flexible-Function Computing”. In addition to configurable hardware, content computing requires software tools, tools flow and software infrastructure to extract content, create hardware configurations, and provide instructions to execute extracted content in hardware. Compute-content is extracted from a high-level language description of an application software program (such as an API), with minimal to no impact on modifying existing code. This is a significant advantage for user adoption of content-computing. CPUs make use of a standard CPU tools flow to convert an application software program to executable hardware instructions. Content computing software tools flow for utilizes an orchestration layer that has a custom tool named Syn-Compiler. The orchestration layer is inserted between expanded source code layer and compiler layer of the standard CPU tools flow—and it can be viewed as a pre-compiler tool. Syn-compiler insert content-computing features into the expanded source code layer, and return it to the standard ISA-compatible compiler of the CPU. The orchestration layer may be inserted at any other position in the standard CPU tools flow. The syn-compiler comprises a combined high level logic synthesis and language compiler tool. Combining logic synthesis with language compilers is novel: it eliminates software to hardware indirection associated with all prior-art compilers. For accelerators, the CPU-accelerator interaction efficiency is described as loosely-coupled and tightly-coupled architectures; both include Control and Status Registers (CSR) for data exchange, both incur various degrees of data transfer penalty to get data to the accelerator for execution (and back). Content-computing uses a directly-coupled, or pipelined-coupled architecture, CPU-instructions and accelerator-instructions using the same coherent cache memory, and have no data transfer delays. Content-computing facilitates back-and-forth computing between CPU hardware and accelerator hardware. Advantages lead to significant performance and power benefits. Thus, the syn-compiler is a combined synthesis & compiler tool, that includes a plurality of features. It identifies a content in an application software program that is targeted for hardware implementation to achieve some value advantage (such as higher performance, lower power, better reliability, better thermal stability, voltage/power management—the content value). This may be done by a user-intervention in using a pragma-wrapper to identify a code-block in the source code, or by selecting a repetitive code block from standard ISA-compiled code. Generate software code targeted to hardware that describe the hardware function using hardware description language (HDL), or any other form of hardware language description automation technique, or selected from a Soft-IP or Firmware-IP library, or by custom coding. Syn-compiler synthesizes a net-list for the targeted hardware function. This may include a Software Development Kit (SDK) that uses Verilog/RTL input code to generate gate-level functional descriptions, gate connectivity, and timing. The SDK will further generate a bit-level description (Bit-Stream) to place and route the hardware function in a programmable fabric, termed the Flexible Accelerator Unit (FAU), in the macroprocessor. The generated bit-stream will program the content-compute hardware image. A collection of pre-defined hardware images comprises a Firmware-IP library that is used in content-computing. Syn-compiler generates the compiled hardware instructions to execute the targeted hardware function. These instructions are available in existing ISA-instruction sets of standard CPUs to support external accelerators. The difference here is that the hardware function is contained inside the CPU-pipeline of a macroprocessor. After the syn-compiler intervention, the user application will contain syn-compiler encoding of user content hardware instructions that remain untouched (pragma-wrapped) during subsequent layers in the standard tools flow. Syn-compiler generates hardware functions from user application software programs to create a value in user identified content computing code block. This identification may be automated so. This automation may use AI learning so that domain specific application programs may have a learned selection of application code-blocks that benefit by hardware implementations. These AI-learned hardware images may be used as Firmware-IP by the syn-compiler. Syn-compiler improves the data bandwidth by significantly eliminating micro-instructions that would have resulted in a standard CPU compiler of that function. Use of a configured-ASIC hardware accelerator leads to significant power reduction.

Syn-compiler software tools facilitate users to partition application software at the high-level language as modules, and use modular interfaces, and in-module content-computing hardware blocks to extend software performance optimization into hardware performance optimization through software. This software-ASIC allows content-computing hardware modules available as firmware-IP for software developers to optimize (modular partitioning) application software programs for performance and power.

Syn-compiler software tools facilitate standard static compilers in the CPU-industry to create groups of repetitive compiled ISA-instructions (code-patterns) to be concatenated into functional accelerator instructions, to eliminate code density, improve performance and lower power. Prior-art compiler cannot create Hardware-Functions; they can only assemble larger hardware-functions by combining existing pre-defined hardware functions. With a syn-compiler, the standard ISA-compiler may conduct timing estimates of compiled-code-blocks, then convert the code-block to a custom hardware execution iteratively to optimize performance. This is a compiler-automation in conjunction with syn-compiler to optimize a cost-function (cost is speed, power, reliability, area, and many other IC-metric) in an optimization routine. Content-computing facilitates automated optimization of user application programs on user defined cost-functions. Syn-compiler is used to dynamically optimize run-time code in instruction queues of CPU-pipelines.

This invention will be more fully understood in conjunction with the following detailed description taken together with the drawings.

### BRIEF DESCRIPTION OF THE DRAWINGS

FIG. 1A shows a prior art computer processor unit (CPU) architecture.

FIG. 1B shows a prior art CPU-pipeline comprising 5 pipelined stages.

FIG. 2A shows a prior-art Register-Transfer Level implementation of a hardware logic-unit.

FIG. 2B shows a prior art logic tile of an FPGA that has logic blocks, logic elements and programmable interconnects.

FIG. 2C shows a prior art embodiment of a CPU with an embedded reconfigurable processor.

FIG. 3 shows a prior art microprocessor (aka CPU) tools flow to convert a high-level language application software program to HW executable code to execute in the CPU.

FIG. 4A shows a first embodiment of a software tools flow to facilitate content-computing in accordance to the teachings of this invention.

FIG. 4B shows an application program software code selected for hardware implementations using custom integration orchestration layer.

FIG. 4C shows a block diagram of a content-computing processor (aka a macroprocessor) HWA that is tightly coupled to the software architecture in Fig-4A.

FIG. 5A shows a configurable content-computing processor comprised of pre-defined CPU hardware, and user configurable hardware in Flexible-Hardware-Unit.

FIG. 5B shows a plurality of content-computing processor units, where the user configurable FAU hardware is contiguous to instantiate very large user defined functions.

FIG. 5C shows a modular implementation of an application software program, where the hardware is partitioned to position a plurality of software modules, and where the contents of a software module and the module interfaces are programmed into hardware FAU structures.

FIG. 6A shows an embodiment of a content compute processor having 7 stages in CPU-pipeline.

FIG. 6B shows dynamically alterable pipelining of a plurality of configured content-compute functions for concatenated sequential operation.

FIG. 7 shows an embodiment of a tools-flow where the syn-compiler is inserted between two layers of a standard CPU tools-flow.

FIG. 8A shows a first embodiment of a dynamically reconfigurable interconnect structure in a configurable CPU pipeline.

FIG. 8B shows a second embodiment of a dynamically reconfigurable interconnect structure in a configurable CPU pipeline.

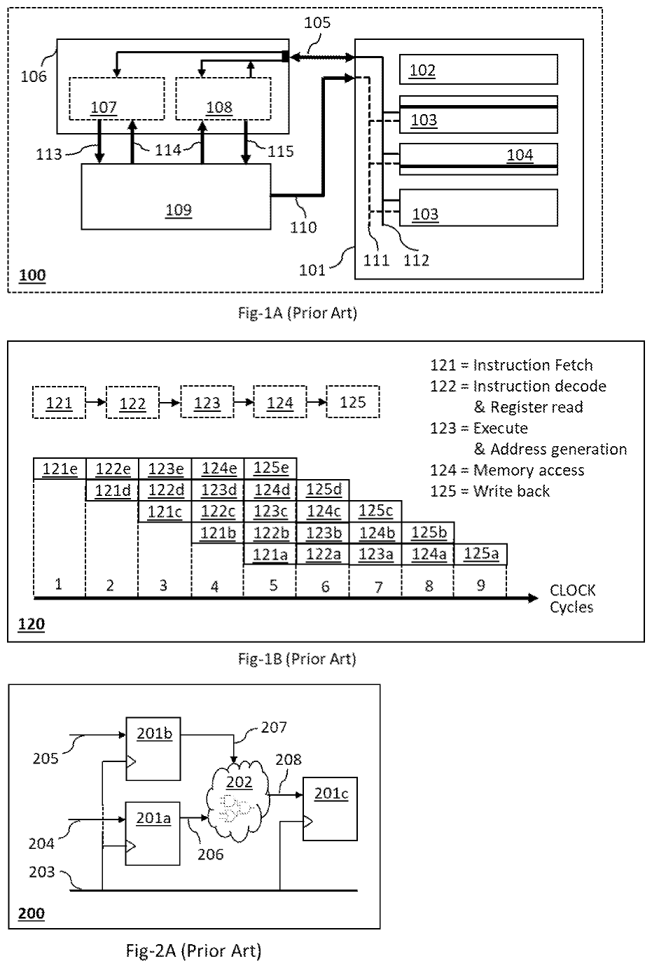

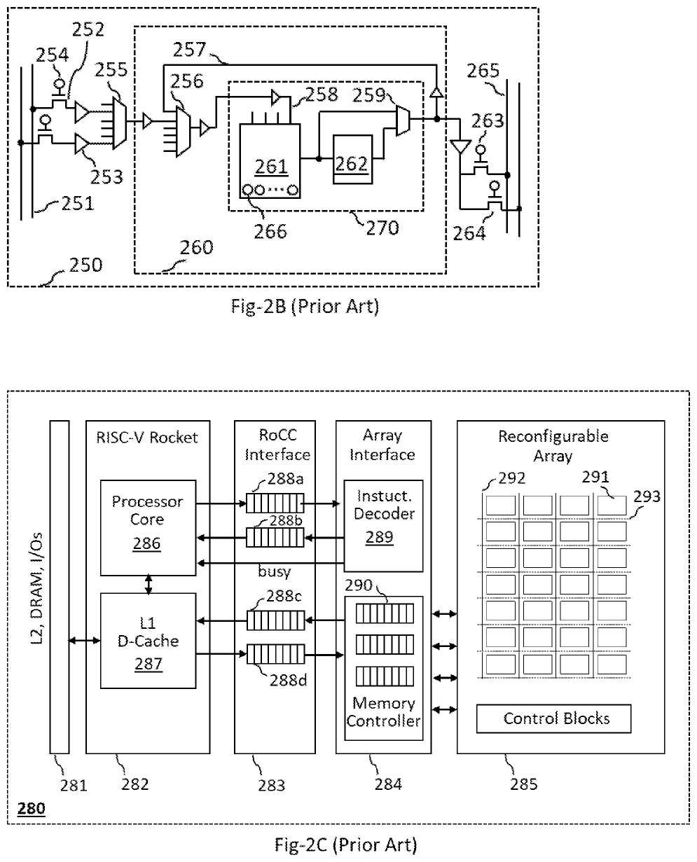

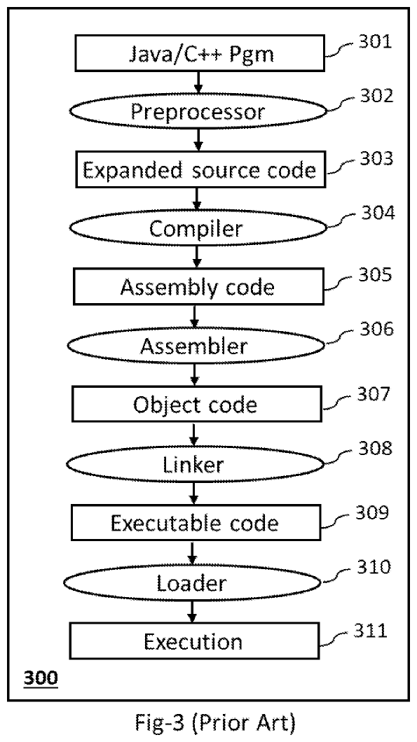

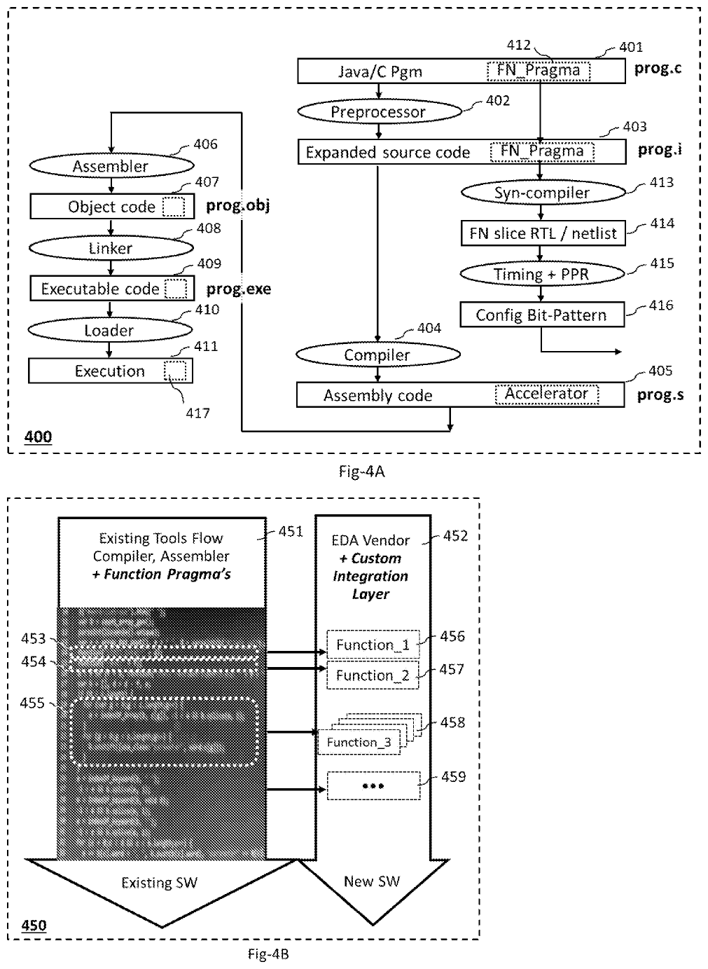

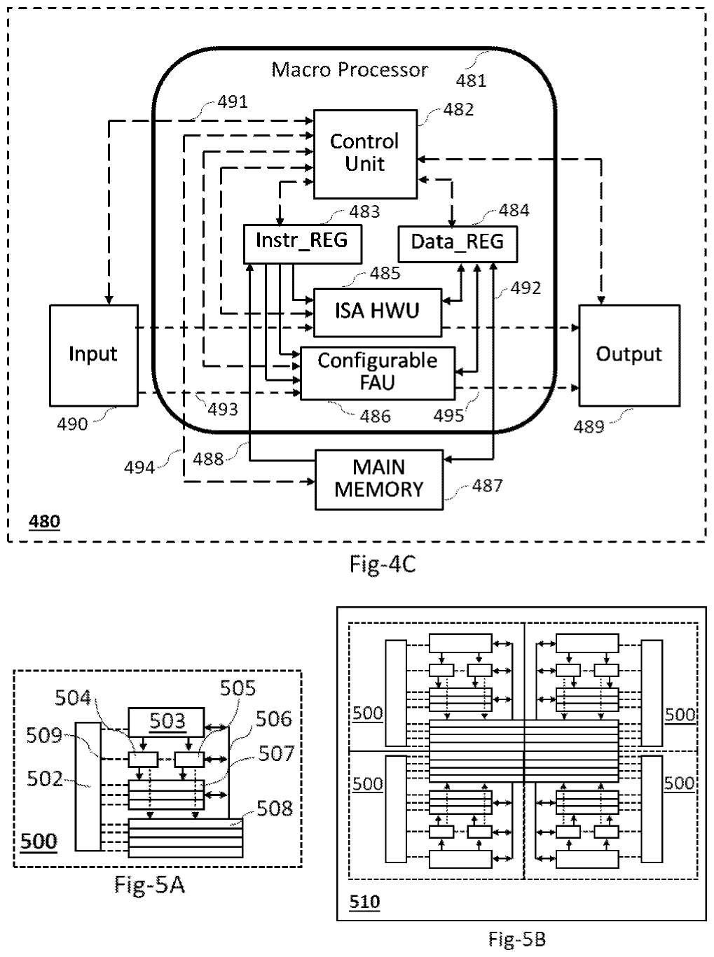

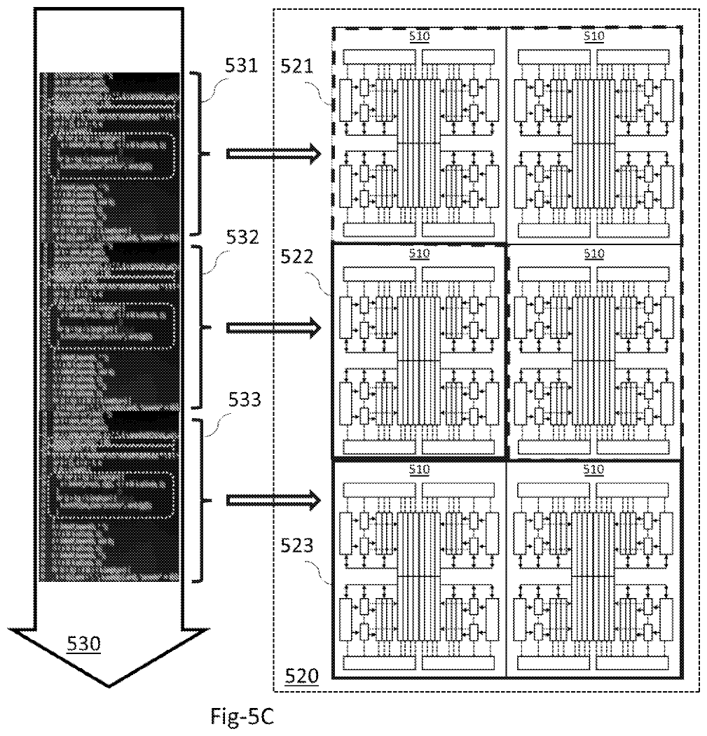

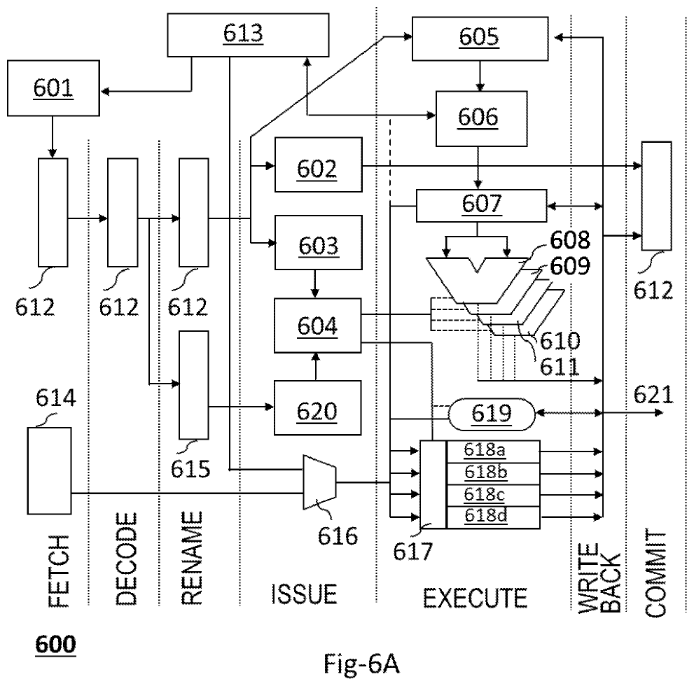

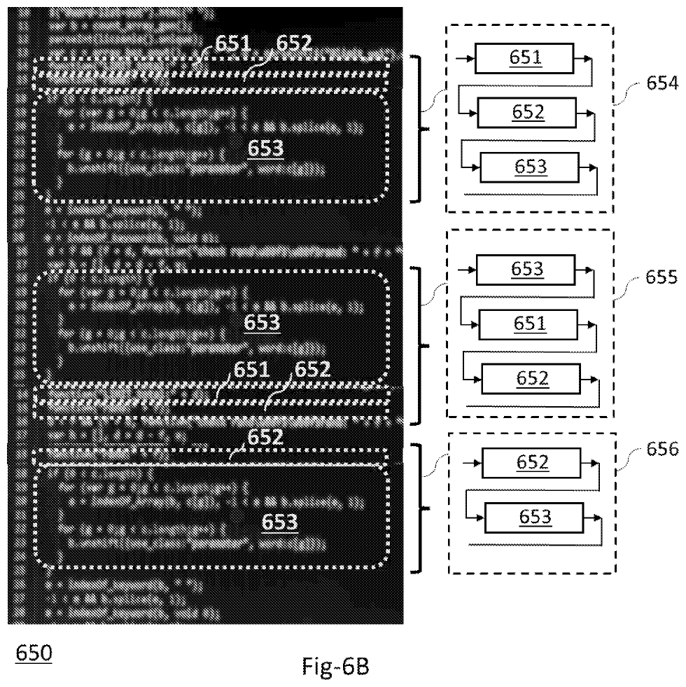

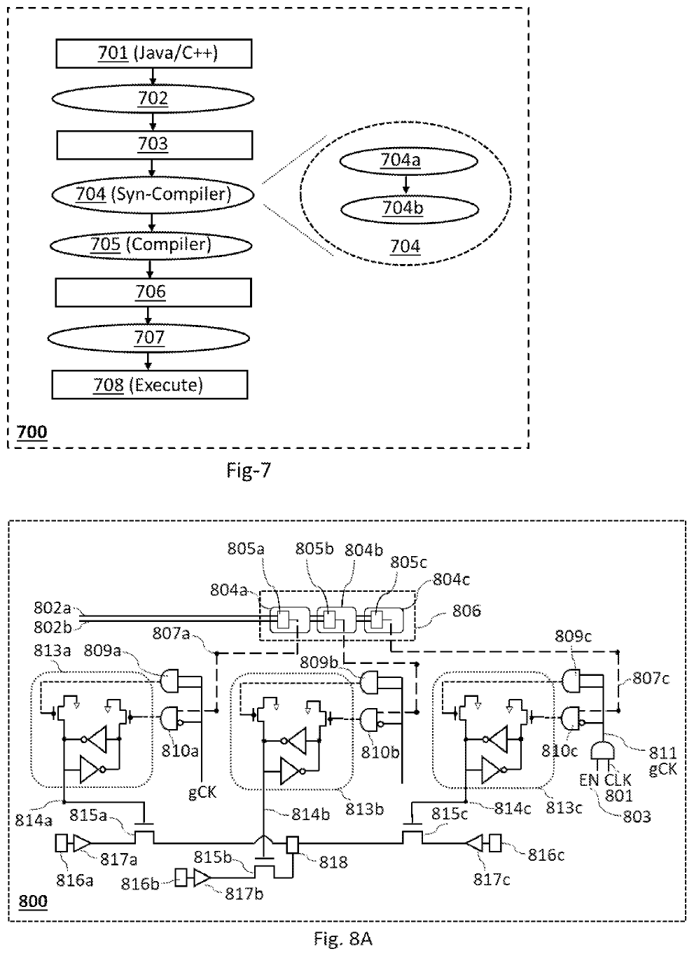

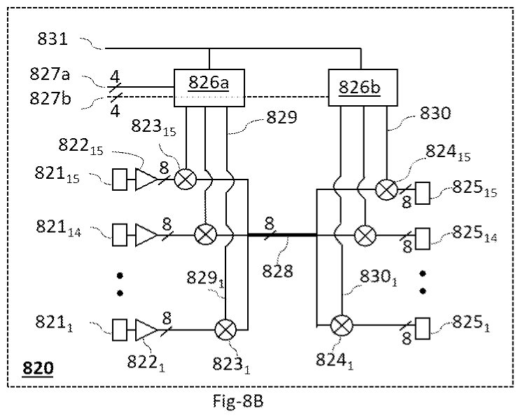

### DETAILED DESCRIPTION

In the following detailed description of the invention, reference is made to the accompanying drawings which form a part hereof, and in which is shown, by way of illustration, specific embodiments in which the invention may be practiced. These embodiments are described in sufficient detail to enable those skilled in the art to practice the invention. Other embodiments may be utilized and structural, logical, and electrical changes may be made without departing from the scope of the present invention.

The terms microprocessor and computer processing unit (CPU) used in the following description include any structure that can receive instructions and data, execute the instruction specified operations, generate a result, and store that result. The structure comprises ISA-instruction set defined (pre-defined) electronic circuits in an integrated circuit (IC) device. The structure includes: memory, control-units, L/S units, decode circuitry, memory-tags, storage buffers, memory management units, cache structures, registers and other electronic circuits that are used to construct CPUs. A CPU-pipeline is defined to be a collection of pre-defined structures comprising a number of stages to completely process an instruction from the time it is fetched from a memory location (such as instruction-cache) to the time it is retired after completing the instruction and storing the results back into memory (such as data cache) if needed. CPU-pipeline stages are bounded by registers.

Macroprocessor is defined as an integrated circuit that has features, and capabilities that exceed microprocessors. A macroprocessor includes the features and capabilities of ASIC's (including gate-arrays), microprocessors and FPGA's. Features include: hardware architecture, firmware, instructions, resource content & configurations. Capabilities include: performance, power, price, quality, CPI & other metrics. Macroprocessor comprises: an ISA, and a fixed-function HWA to execute the ISA-instructions; and user specified functions, and a configurable HWA to program and execute the user functions.

Content compute processor is defined as a processor that is able to extract content from an application program in the form of one or more function instructions, and execute the extracted content (i.e. functions) in one or more compute cycles. A plurality of ISA compatible instructions may be compacted to a single function instruction. A plurality of ISA-instructions may be grouped in parallel to obtain a Multiple-Instruction-Multiple-Data function instruction that is executed in HW in one cycle. A content compute processor may involve use of software tools, software development kits (SDKs), software infrastructure and tightly coupled software-hardware architectures to enable user identified high-level language software blocks to be converted to function instructions for content computing. Software infrastructure facilitates content computing in a macroprocessor. A content compute processor is a macroprocessor configured to execute software defined content, as opposed to executing compiled micro-code in pre-defined ASIC & ISA HW functions.

This invention is to construct various embodiments of a content processing unit (macroprocessor) and tightly coupled software architecture that has the capabilities and features of a microprocessor, graphics processor, gate array, field programmable gate array, and application specific integrated circuit. A macroprocessor comprises a microprocessor, which has an ISA & HWA similar to a custom processor, ARM processor, x86 processor, MIPS processor, and RISC processor. Macroprocessor ISA attempts to make no changes, or minimal change, to an existing microprocessor ISA. Macroprocessor is not a co-processor that expands ISA. The microprocessor may comprise one or more of: memory units, registers, arithmetic logic units (ALU), floating point units (FPU), address generation units (AGU), branch predictor and program counter unit (BRU), shifters, comparators, multipliers, integer processing units (IPU), digital signal processor units (DSP), Analog Circuits, clocks, phase-lock-loops (PLL), delay lock loops (DLL), drivers, buffers, repeaters, clocks, and other circuits found in CPU circuits. A macroprocessor comprises field programmable gate arrays (FPGA). The FPGA may comprise one or more of: memory units, LUs, FPUs, carry-logic units, shifters, configurable logic elements, look-up table logic blocks, comparators, multipliers, DSPs, adders, Analog Circuits, clocks, clock divide/multiply, PLLs, DLLs, configurable segmented interconnects, drivers, buffers, registers, flop-flops, and other circuits found in FPGA devices. A macroprocessor comprises embedded application specific integrated circuits (ASIC). The ASIC may comprise custom functions that are specifically designed to do complex functions, including hard-IP & soft-IP that can be integrated into chip design. Memory may comprise any volatile or non-volatile memory element, including SRAM, flash, EEPROM, MRAM, eFuse, laser-fuse, DRAM and state-transition memory. Macroprocessor software architecture facilitates application software to run on the macroprocessor independent of user familiarity in HWA. A macroprocessor SDK includes a logic synthesis, gate-level logic synthesis, LUT-packing, place & route software & timing-analysis and optimization. An SDK includes traditional FPGA SDK components.

An exemplary Microprocessor 100 according to prior art is shown in FIG-1A. An external memory unit 101, a Solid-State Drive (SSD), stores all the data. Computer boot code, compute data, and instruction data may be stored in a region 101, 102, 104, and 103 respectively in memory 101. Inbuilt control bus 111 selects memory address, inbuilt data bus 112 transfer memory data from the memory address. Inbuilt logic in 101 (not shown) complete read/write memory functions based on control signal 111 information. In von-Neumann & Harvard architectures, CPU 100 comprises a data unit 106 and a control unit 109. Memory 101 couples to data unit 106 via bus 105, and to control unit 109 via bus 110. Data unit 106 may further comprise an instruction-register (I-cache) unit 107, and a compute-data (D-cache) unit 108. In Harvard architectures, they use independent data buses. Control unit 109 generates all hardware signals (level signals, pulse signals, hard-ware control signals, data transfers, etc.) to ensure execution accuracy. Control unit 109 receives instructions from I-cache 107 via data path 113; and it generates control signals 114 to keep I-cache & D-cache synchronized using data flags on 115. It also ensures continuity of instructions. Control unit 109 may respond to external controls (not shown, such as those generated by operating system or a thermal management system).

CPU 100 is architected for cyclical operations. A CPU-pipeline for improving compute efficiency is shown in 120 of FIG-1B. In FIG-1B exemplary 5-stage pipelined HWA, most stages take one clock cycle to complete. Memory access 124 may take at least two cycles, one to set up an address (& data for a write), and a second to read/write data from/to that address. Execution unit 123 has variable latencies based on complexity of the function (an FPU divide can take ˜20 cycles). Blocks 121-125 show five pre-defined hardware units. Letters a-e are five consecutive instructions; all instructions occupy different stages of the CPU instruction pipeline 120 during cycle-7. It is common to see 3-stage, or 7-stage, or even 20-stage CPU-pipelines. A super-scalar may have multiple parallel 120 structures. An ideal 4-wide CPU-pipeline can execute 4 instructions simultaneously. Normally this is not the case: most often the instructions per cycle (IPC) drops to ˜2. Best in class computers, utilizing 2-threads, each thread 4-wide, may achieve IPC˜3 today. This is due to inefficiencies in loading parallel hardware units simultaneously, data dependency, interrupts, cache misses and out-of-order (OOO) instruction management. Of all 5 instruction stages shown in FIG-1B, only the hardware unit in 124 executes a useful activity that computes a data transaction, and modify data. Remaining 4 stages in the 5-stage CPU-pipeline 120 simply move data around to set up the one useful data activity in 124. Reading and writing data are needed activity, and pipelining intent is to hide the cycles needed behind a useful hardware execute cycle (i.e. do in parallel). In RiscV, an ALU add [ADD rd, rs1, rs2] requires 3 cycles: (i) load rs1, (ii) load rs2, (iii) set-up ADD function in ALU—execute—write rd. Control unit facilitate all of these HW functions using ISA-defined HW functions that are selectable by N-bit (N=4-12) control-signals. HWA is constructed to make this possible. There are only a limited number of hardware units available in a CPU: such as ALU, FPU, etc., all having a pre-defined set of functions. When a more advanced function is needed, it must be built—or compiled—with the known set of ISA-defined HW functions. These prior-art compute machines are hereby defined as cycle-compute processors and cycle-computing architectures. Application developers use high level programming languages such as C++, Python, Java to write the code. Software compilers and assemblers convert those application SW to ISA compatible machine code that will run on a cycle-compute processor. This conversion leads to indirection and inefficiency.

A prior art RTL based logic function 200 is shown in FIG-2A. Logic function 200 is built using standard cell (or gate array) logic gates, synthesized, placed & routed using CAE-tools to ensure functionality and timing accuracy. Inputs 206, 207 and output 208 of logic function 202 are registered in 201a-201b-201c respectively. Clock is 203, and 204 & 205 are register inputs. Registers 201 may be D-flip-flops, or SR-flip-flops, or any other comprising master/slave stages to prevent feed-through. In one clock cycle, 1000s of logic gates in 202 function is executed, result captured in register 201c. Embedded Application Specific Integrated Circuit (ASIC) in CPUs cost too much, takes too long, and gets obsoleted quickly.

A detailed view of logic hierarchy and connectivity of a complex logic tile in prior art FPGA is shown in FIG-2B. Input data arrives in a plurality of wires (aka interconnects) 251. Selected inputs are coupled to tile 250 by a configurable switch matrix, each switch comprising a configuration bit 254 and a pass-gate 252. 253 is a buffer. 257 is a local feed-back from logic element 270. The configuration bit 254 is a memory element having output states of logic zero, or logic one. A plurality of selected (configured) inputs is available for logic in tile 250. A configurable multiplexer 255 selects one or more of those tile inputs to reach a logic block 260. There are a plurality of such logic blocks 260 in logic tile 250, each logic block selecting same or different inputs from tile inputs. Inside logic block 260, there is a plurality of logic elements 270, each logic element 270 choosing its inputs via configurable multiplexer 256. Configurable multiplexers also have a plurality of configuration bits such as 254. Logic element 270 comprises LUT-logic unit 261 and register (or flip-flop) 262. The LUT-logic unit contains configuration bits 266, named LUT-values, that when configured, define its logic functionality. In the illustration a 4-input LUT-function (notation 4LUT) is shown. 4LUT 261 has 16 configurable LUT-values 266. These 4 inputs and 16 LUT-values are needed to build the 4LUT function. Hard input values 0 & 1 are also available as inputs. The output of 4LUT 261 can be latched in register 262, or by-passed via configurable multiplexer 259 to another logic element. Output of 261 can be fed back to logic block 260, or to tile 250 for sequential logic, or taken out of the tile to a chosen wire from a plurality of available output wires 265 via configurable switch matrix having a plurality of configuration bits 263, and pass-gates 264. A plurality of sets of logic elements 266 combine to form a logic block 260 function. A plurality of logic block 260 functions combines to form a logic tile 250 function. Ensuing end complex logic function is named a LUT-tree. A segmented interconnect structure, connected thru a configurable switch matrix provide the mesh to connect logic blocks and logic tiles to one-another. The entire collection of configuration bits is connected to a configuration circuit to facilitate programming of memory bits. The configuration is usually arranged in a row-column grid system, similar to a memory array, so that all the configuration bits can be programmed by standard memory programming techniques; one row at a time. In an FPGA, there can be 100's of millions of configuration bits, and a bit-pattern that define the status of every single bit specifies a valid design implemented in the FPGA. For volatile SRAM based FPGAs, the configuration circuit must upload a valid bit-pattern from a storage boot-ROM in the system. This happens immediately after power-up of the FPGA, and take up 1000's of cycles to program the bit-pattern.

A prior art co-processor extension of a CPU core using a reconfigurable array is discussed in Ref-2. Their FIG-1 is summarized in 280 of FIG-2C (for convenience of the reader) to show prior art in embedding reconfigurable fabrics with CPU's. The combined architecture in 280 shows a microprocessor 282 interacting with a co-processor comprised of a reconfigurable-array 285 and an RoCC interface 283 and array interface 284 (comprising registers 290), the interfaces positioned serially in between the two units. The CPU 282 loads data into D-Cache 287 from a memory unit 281. Co-processor uses new instructions to program and use reconfigurable array 285, an expansion to Risc-V ISA of CPU-core 286. Reconfigurable array 285 comprises vertical wires 292, horizontal wires 293 and an array of logic blocks 291. This reconfigurable-array 285 is programmed to provide pre-defined “small” set of functions such as: add, shift, select, table look up, etc. Each new function in the set is defined by a configuration-file. Use of co-processor requires 3 instructions: (i) an instruction to load a “configuration-file” to program array 285, (ii) an instruction to setup inputs in RoCC 283, (iii) and an instruction to retrieve the result from RoCC 283 when done. Only defined co-processor functions can be programmed by this method. There is no provision for a user to convert a user defined function into co-processor. In a microprocessor, this is done by a compiler: it converts the user-defined function to a series of microprocessor ISA commands. The authors describe many difficulties & inabilities encountered during their effort in using high-level RTL design, synthesis, and place & route using 3^{rd} party tools to extract co-processor configuration-files.) Use of an embedded co-processor limits the usefulness to the few enhanced instructions enabled by ISA-expansion. For array 285, each co-processor instruction is 64-bit of data to identify interconnects and logic in look up tables. Registers 288 (288a-288d) facilitate instruction-data and compute-data transfers. Other prior-art teachings (not shown) discuss use of two-chip solutions: CPU to request an external chip to compute a pre-defined function (an accelerator), send a request with data to use the accelerator, wait for a done response and retrieve the final result. This mode of accelerator use can work for embedded accelerator cores as well, and is similar in concept to 280 of FIG-2C, without the configuration-file defining the function. A busy-signal (similar to instruction decoder 289 interaction with processor core 286) monitors the availability of the Function-Accelerator. Embedded-accelerators and co-processors do not have the flexibility of the FPGA 250 (FIG-2B), where the software infrastructure and RTL design methodology enabled the FPGA to implement any user function, provided it is coded in RTL. There is a need for new software infrastructure and use of flexible-ASIC accelerators to enhance CPU performance, without the limitations discussed above with respect to co-processors in FIG-2C.

The impact of instruction overhead for dynamic re-configuration of array 285 in FIG-2C is significant. A 24×32 array 285 requires 24*32(=768) 64-bit configuration instructions. Assuming a Load-Store 32 b CPU for 120 in FIG-1B architecture, for a 32 b Add [(LOAD addr1 A), (LOAD addr2 B), (ADD addr, addr1, addr2), (STORE addr3 addr)] to compute 64 b compute-data in CPU, we need 4×32 b instructions. That is 67%/33% instruction-data/compute-data ratio for IO-bandwidth. If we do 250 k ADD's consecutively, for 1M lines of instruction code with 250 k computes, we need total (1M*32+250k*64) 6 MB IO-data. We have 4 MB instruction data+2 MB compute data adding up to 6 MB. Had we used 10% of Add computes as reconfigurable-Add (changing each time) in array 285, we need (25k*768*64) 1228 MB extra config-instruction data. This is an astronomical 200× increase in total data bandwidth that IO's must provide. This is only practical if the configuration data was stored in local memory at boot-time (meaning load it once at power up so IO bandwidth is not wasted). We need interrupts to stop execution to reconfigure Array 285. Interrupts & 768 cycle reconfiguration latency is neither practical nor useful in computing.

FIG-3 shows a prior-art software tools flow 300 that convert high-level language application software 301 to hardware execution 311. In FIG-3, ovals are software tool that process the application program, rectangles are resulting “converted” application program. A preprocessor tool 302 generates expanded source code 303, a compiler tool 304 generates assembly code 305, An assembler tool 306 generates object code 307, a linker tool 308 generates executable code 309 and a loader tool 310 provides the execution 311 of original software program 301. User interfaces, operating systems, ease-of-use, memory footprint, user knowledge, and various usage necessities form the infrastructure needed to deploy these software tools. Interrupting or modifying existing software tools flow 300 with custom tools is a significant barrier to entry in hardware adoption.

A first embodiment of software tools and software architecture for a content computing is shown in 400 of FIG-4A. The overall software execution flow is shown in 450 of FIG-4B. The discussion below will refer to FIG-3 to illustrate novel features associated with content computing, in the form of an orchestration layer, without modifying the standard tools-flow. In 450, existing tools flow 451 includes all software features shown in prior-art 300 of FIG-3. In 450, the application developer or user identifies high-level language functional calls 453, 454, 455 using pragma-wrappers. A pragma-wrapper acts as a directive for integration software 452 to provide additional information to the software program. A wrapper function (another word for a subroutine) in a computer program (or software library) calls for a substitution with no additional computation. In our usage, the pragma-wrapper acts as a pass-through directive in the existing software flow 451, asking for a custom integration flow 452 to provide a substitution function. For example, pragma-wrapper 453 is provided with Function_1 456, etc. As a second example, pragma wrapper 455 may be replaced by a plurality of functions 458: it may be a Function_3 duplicated in multiple instances, or different functions either in series or parallel. In all cases, inputs & outputs of both functions 453 (in main flow) & 456 (in pragma flow) are identical. Once the pragma-wrappers are drawn, user does not require custom integration flow 452 knowledge to generate functions 456-459, and that will be discussed later. However, a knowledgeable user may be able to provide a more-efficient implementation of Function_1 456 compared to the auto-generated Function_1 produced by custom integration software 452. That too will be discussed later. Function_1 may be taken from a library.

In 400 of FIG-1A, 401 shows the user program prog.c written in high-level language such as Java, C++, Python etc., wherein pragma-wrappers FN_Pragma 412 are identified. These may be complex function calls (such as an AES Encryption/Decryption call, or an enterprise search Find_Prefix call), or a highly repetitive instruction (such as 32×32 Matrix Add's that can be parallelized), or a custom instruction (CISC) for a specific function that occurs frequently in the program. A CISC instruction may comprise a sequence of ISA-compatible (say RISC) instructions. In all cases, a plurality of machine instructions is compacted into a single Function call by FN_Pragma 412. In some cases, 1000's of lines of instruction code may be replaced by 1-line of function code. This reduction in instruction-data is a significant increase of IO-bandwidth to compute-data. Preprocessor 402 treats the FN_Pragma 412 as a pass_through, and expanded source code prog.j 403 maintains the software program structure with FN_Pragma 412 boxes. A FN_Pragma 412 provides content processing instruction to HWA as a plurality of ISA-instructions were compacted to create the single content processing function instruction. A custom set of software tools translate FN_Pragma execution in macroprocessor hardware. The custom integration software program 452 (FIG-4B) is described next.

In FIG-4B, FN_Pragmas 453-455 in 450 are high-level language functional descriptions of a plurality of subroutines. A function comprises inputs, one or more processing actions to the inputs, and generate one or more outputs. A function maps a plurality of inputs to a plurality of outputs. In a first embodiment, an RTL designer generates RTL description for the mapping function. In a second embodiment, an automated software tool generates this mapping function. These functions may be provided in an RTL-library for users to use, a common practice in open-source software libraries today. Syn-Compiler 413 in 400 has a synthesis module and a compile module. Generated RTL is parsed through an EDA vendor synthesis module in 452 (such as Synopsis, Cadence, Siemens, etc.) that converts RTL-code to a netlist of gates & nets (interconnects). Each FN_Pragma 453-455 generates a synthesized netlist 414 in 400. An HWA knowledgeable PPR_Tool (pack, place, route) in 400 generates logic packing into look-up-tables (LUT), LUT placement, connecting logic, and timing optimization 415 to create a hardware-macro that replicates each of FN_Pragma 453-455 behavior. This will be described in 480 of FIG-4C. The PPR_Tool is generic to standard FPGA implementations of RTL-designs, except it has knowledge of HWA 480 in FIG-4C to implement the hardware-macro in configurable FAU 486 of FIG-4C. The compiler module in syn-compiler 413 generates logic, interconnect, driver and register information in function instruction 412 in 400 (or 453-455 in 450) to execute in HWA 480. The PPR-Tool generates configuration bit pattern 416 that would: identify input connections (ports), output connections (ports), and logic function & connections between inputs & outputs. The outputs may be registered or unregistered. Each hardware-macro is placed into a configurable FAU HW unit, such as 486 in FIG-4C, provided in HWA. In generating a hardware-macro, the timing optimization tool calculates a latency for time delay between Input-Output signals (as an example, say 3 cycles). In another embodiment, the PPR_Tool forces the Input-Output delay as a series of clock-indexed steps (as an example, say 3 steps of 1-clock cycle), using registering outputs at every single clock-cycle. In the latter example, the 3 steps are auto-pipelined, meaning 3 consecutive input-data can be consecutively processed in the 3 hardware stages to improve compute efficiency. Expanded source code in prog.i 403 in 400 is fed to a standard ISA-compatible compiler 404 that compiles ISA-instructions. Standard compiler 404 leaves the syn-compiler 413 instantiated instructions untouched. The compiled assembly code 405 in 400 is augmented with FN_Pragma driver/register instructions. The enhancements are shown in dotted-box, and labeled Accelerator, in 405 of 400. The rest of the tools flow shown in 406-411 are standard CPU tools, same as 306-311. The new exception is FN_Pragma 412 gets replaced by a function instruction 417 that calls for a user customized hardware-macro, containing information on where (registers) to locate inputs, and where (registers) to write outputs and other needed driver settings. Content compute software flow in 452 of 450 provides a method to use existing software EDA tools, existing ISA and ISA compatible compilers, assemblers, etc. with the customization restricted to an orchestration layer within the tools-flow. It also provides a method to use demonstrated and proven FPGA software development kit (SDK: PPR_Tools, bit-streams) methodology to create hardware-macros to replace software functions within an existing CPU ISA, and augment drivers to execute function instructions in configurable FAU units.

480 in FIG-4C shows an HWA that is tightly coupled to the software architecture 400 (FIG-4A) and 450 (FIG-4B). Instruction-data and compute-data is received into main memory 487 by IO's provided in the integrated circuit, and its data rate is determined by IO-bandwidth. For convenience, memory 487 can be viewed as L3/L2-caches. HWA 480 comprises a macroprocessor 481 coupled to inputs 490 (to receive external controls), outputs 489 (to supply status) and memory unit 487 (to receive instruction/compute data). Macroprocessor 481 has at least one ISA compatible hardware unit (ISA HWU) 485, and at least one Configurable FAU unit 486. There may be a plurality of each (485 & 486) in a macroprocessor 481. Macroprocessor 481 comprises a control unit 482 coupled to all hardware blocks to manage data-flow and select HWU (485, 486) function. A group of instructions reside in instruction register 483, and corresponding tagged data resides in data registers 484. An issue queue (not shown) issues instructions to available HWU, such as 485 & 486. A hardware-macro generated by custom integration layer 452 in FIG-4B is programmed into configurable FAU 486. This may be done at boot-time using configuration bit-pattern 416 in FIG-4A. When this is done during boot-time, it does not impact IO-Bandwidth during operating time one-time. A plurality of configuration bit-patterns 416 may be stored in main-memory 487 during boot-time. Re-configuring configurable FAU from 487 to a new function during run-time does not affect IO-bandwidth, as the reconfiguration data reside inside the integrated circuit. This storage may be accommodated by virtual memory partitioning in L3-cache. These bit-patterns may be provided as a “bit-pattern library” for users to directly convert pragma-wrapper functions 412 in configurable FAU 486 to bit-patterns. Other embodiments of dynamic reconfigurability are disclosed in the incorporate by reference provisional patent application. Once configurable FAU 486 is programmed to implement FN_Pragma 412, the new function instruction substituted by the wrapper only require a pointer to the input register (to feed input data) and a pointer to output register (to fetch the results) and a latency (#clock delay to know when the output is ready). This is a significant reduction in instruction overhead. A first instruction in instruction registers 483 may be executed in ISA HWU 485 (such as an Add function in ALU). A second instruction in instruction registers 483 may be executed in Configurable FAU 486 (such as an AES decryption programmed into 486). In a preferred embodiment, these instructions may be executed concurrently by appropriate issue-queue design. In macroprocessor 481, the output of a first hardware unit may be used by another hardware unit as input. ISA HWU 485 is an ISA-instruction cycle-compute unit, whereas config FAU 486 is a function instruction content-compute unit. In FIG-4C, control unit 482 couples to input 490 via bus 491, to main memory via bus 494. Config FAU 486 couples to input 490 via bus 493, and to output via bus 495. Main memory 487 has access to data register 484 via data path 492, and to instruction register 483 via data path 488.

A software method 450 is provided for functional instruction content computing, the method 450 comprised of: using a pragma-wrapper to identify a high-level language function; generating an RTL (or Verilog) model to replicate the pragma-wrapper function; synthesizing the RTL-code to create a netlist; using a configurable FAU logic block to place and route the netlist and extracting a bit-pattern to program the pragma-wrapper function as a hardware-macro function.

A software method 400 is provided to implement a high-level description language function statement in a programmable logic block comprising a plurality of configuration bits, the method 400 comprised of: using a pragma-wrapper to identify a high-level language function; generating a configuration bit-pattern to program the pragma-wrapper function in the programmable logic block as a hardware-macro function. The method 400, wherein generation bit pattern comprises: using an RTL (or Verilog) model of the pragma-wrapper function; synthesizing the RTL-model to a netlist; using a place and route software tool to generate the bit-pattern.

A content computing processor 480 in FIG-4C comprising: a configurable logic block 486 comprised of a plurality of configuration bits; and a programmable method 400 comprised of: identifying a high-level software language function using a pragma-wrapper; and converting the pragma-wrapper function to a hardware-macro by generating a bit-pattern to program the configurable logic block. Processor 480 further comprising: instruction registers 483 and a control unit 482 to selectively execute an instruction in an ISA compatible hardware unit 485 and a pre-configured ASIC unit 486.

A method of content computing 400 in FIG-4A comprising: using a pragma wrapper 412 to identify a software function; converting the identified function to a bit-pattern 416 that can program a programmable logic block 486 to execute the pragma wrapper function.

A typical content compute unit 480 in FIG-4C includes many ISA compatible hardware units 485 and configurable FAUs 486. The configurable FAU is constructed as a plurality of programmable slices called FAUs in this disclosure. This is shown in 500 of FIG-5A. In 500, 502 is the control unit coupled to all hardware blocks; 503 is a local shared memory unit such as L2-cache; 504 is the L1 I-cache that stores instructions; and 507 is the L1 D-cache that stores data. 507 is one or more of ISA-compatible HWU such as ALU, FPU, BRU, etc. such that each HWU instruction has a matching ISA defined compiler translation. 508 is a plurality of FAUs arranged in a layout arrangement so that the FAUs can be combined to build larger Hardware-Macros. A FN-Pragma 412 in FIG-4A may be positioned in one FAU, or a plurality of FAUs. Outputs of ISA-HWU 505, and FAUs 508 are coupled into data bus 506, as well as L2-cache 503 to exchange data. Instructions in 509 may be executed in ISA-HWU 507, and/or FAUs 508. A plurality of instructions may be executed concurrently in a plurality of ISA-HWU 507 and a plurality of FAUs 508 concurrently. It is understood that issue-queues, tags & data flow must be managed to process parallel instructions concurrently.

A plurality of content compute units 500 may be combined into a content compute block 510 as shown in FIG-5B. In this construction, the FAUs are constructed to abut in adjacent compute units such that large FN-Pragmas 412 can be programmed into FAUs 517 that abuts to form a sea of programmable logic gates. A plurality of compute blocks 510 may be combined into a content compute tile 520 shown in FIG-5C. An application software program 530 is shown in FIG-5C. The application software program may be sub-divided into a module 531, module 532 and module 533. This is a system level portioning of a modular application program. Each module interaction with the next module occurs through a communication protocol: input data, interacting control signals, and output data. Each module 531-533 may comprise a plurality of FN-Pragmas such as 412 in FIG-4A. In addition, each module is identified by a modular-pragma boundary. A FN-Pragma is programmed into one or more FAUs as discussed in FIG-4C. A modular-pragma may be positioned in to a plurality of compute cluster blocks 510. For example, module 531 instructions & data may be provided to a first L3 virtual-memory partition, from which it is mapped to L2-cache located in region 521, wherefrom instruction caches and data caches retrieve data to execute. Similarly, module 532 instructions & data may be provided to a second L3 virtual-memory partition, from which it is mapped to L2-cache located in region 522, wherefrom instruction caches and data caches retrieve data to execute. In addition, output data of modules 531 must be received as input data in module 532, in accordance with communication protocol between the two modules 531 and 532. That is managed by register or memory write techniques. This procedure is continued until all software modules are mapped into the HWA. This module placement and connectivity protocol allows application developers to utilize compute processor tile structures for floor planning for modular based code execution. This provides a path to modular content processing in macroprocessor.

A configurable compute processor 520 in FIG-5C comprising: a content compute module 521 comprised of a plurality of content compute blocks 510, each content compute block 510 further comprising an ISA-HWU 507, and a user configurable logic block 507; wherein a software module 531 identified by a module-pragma in a user application program 530 is compiled to execute in the content compute module 521. The configurable compute processor 520 further enabled to receive instruction data and compute data from an external memory device (not shown) to one or more memory units 503 (L2 cache 503 in FIG-5A) within at least one content compute blocks 510. The configurable compute processor 520, wherein a said content compute block comprises an instruction cache (504) and data cache (507) coupled to memory unit 503 to receive instructions and data respectively. The configuration compute processor 520 enabled to execute an instruction in ISA-HWU 507, and a pre-configured logic block 507. A configurable compute processor 520 comprising a user defined module 531 positioned in a configurable logic module 521, the programmable means comprised of identifying a function by a function-wrapper in user program module 531, and converting the function to a hardware-macro defined by a bit-pattern to program a configurable logic block 507 in the program module 521.

A modular compute processor 520 in FIG-5C comprising: a first compute module 521, and a second compute module 522, each of the modules 521 and 522 further comprised of a plurality of content compute blocks 510; wherein a first software module 531 and a second software module 532, each module identified by a module-pragma in a software program, are compiled and positioned to execute in the first and second compute modules respectively. Module processor 520, wherein the boundary between module 521 and module 522 is described by an input-output interaction protocol. A module compute processor 520 in FIG-5C comprising: a first compute module 521, and a second compute module 522; wherein the coupling between said modules 521 and 522 is defined by a module-pragma bounded software module 531 and software module 532 interaction protocol in a user application software program, 530. A module compute processor comprising a first compute module 521, and a second compute module 522; wherein a data compute function implemented in modules 521 and 522 comprises: an input of data compute function coupled to an input of module 521, an output of module 521 coupled to an input of module 522, and an output of module 522 providing an output of the data compute function.

A modular hard-ware implementation method of a software application program 530 comprised of: using a module-pragma to identify a region of software code 531 that has a well-defined functional boundary; using a plurality of pragma-wrappers to identify a plurality of functions in the region of software code 531; synthesizing pragma-wrapper functions to generate a plurality of netlists that is placed and routed in one or more programmable logic blocks 500 of a configurable compute processor 520; identifying a programmable logic module region 521 needed by synthesized hardware-macro placement; using a compiler to identify and position the required instruction and data content for software code 531 in a memory location (L3 cache); and using a memory management unit to load instructions and data from said memory location (L3 cache) to a plurality of memory units (L2 cache) in the hardware units 500 positioned in the modular region 521.

As an example, in an enterprise search program, a user may wish to conduct a document search for a term such as “professor”. All documents are indexed and the inverted-index files are accessed by a search software program with the user query “professor”. The search program may be divided into 3-modules: (1) Find_Prefix, (2) Find_Suffix, (3) Posting_List. Find_Prefix is a graph that may be implemented in module 521, and it will traverse the graph to identify the path of P, R, O, F (F is assumed to be the last node in the graph). Then the container of suffix terms is fetched into module 522. These are all the words that had PROF in common with “professor”. Find_Suffix targets an exact match of remaining characters to provide the address of the list of documents that has “professor”. The document statistics are processed in Posting_List in module 523 to pick best matching documents. This module processes statistics and normalizations to rank all documents that has “professor” to provide the top 20 or 30 documents to look at. A first advantage with the modular partitioning is that when the first query is in module 523, a second query is concurrently in module 522, and a third query is concurrently in module 521. We have auto-pipelined very complex compute functions in the modular compute processor. A second advantage is that any single function such as Find_Prefix, if implemented in ISA-compatible instructions, it would take ˜6000's cycles, whereas in a hardware-macro function, it may take˜120 cycles, a 50× performance improvement.

Another embodiment of a compute processor 600 is shown in FIG-6A. Compute processor 600 comprises L3-cache 614 & L2-cache 613. It includes a microprocessor, similar to FIG-1A, with related hardware components. For illustrative purposes a 7-stage (fetch, decode, rename, issue, execute, write back & commit) pipelined microprocessor (aka CPU) is shown. A CPU includes load-store unit 605, I-cache 601, D-cache 606, data registers 607, control unit 604, ALU 608, FPU 609, AGU 610 & BRU 611 (all shown as ISA-HWU 485 in FIG-4C). A CPU further includes a plurality of register files 612. Compute processor 600 includes: decode logic (not shown) to generate FAU 618 instructions branch-out to a parallel rename register 615, and a FAU 618 specific instruction issue queue 620. A configurable multiplexer 616 allows data selection to FAU 618 from one of L2-cache 613 and L3-cache 614. A plurality of FAUs 618 is boot-time configurable, and/or dynamically re-configurable. Each FAU 618 comprises LUT logic and segmented routing wire configurability. A plurality of FAUs 618 may be combined to build a larger function. Each FAU 618 further comprises DSP slices, carry-logic & registers. Each FAU 618 is further capable of including any other custom hardware units. A plurality of FAUs 618 is coupled to a local data-cache 617, which comprises one or more storage elements, preferably single-port or multi-port SRAM memory. FAUs 618 may receive compute data from one of: L1 D-cache 606, ISA-HWU 608-611 input registers 607, L2-cache 613 and L3-Cache 614. Compute processor 600 comprises a control unit 604 coupled to ISA-HWU 608-611 issue queue 603 and FAU 618 issue queue 620. 602 is the re-order buffer. Executing CPU instruction in 603 activates control unit 604 signals to manage data-flow and functions in CPU section, whereas executing one or more FAU instructions in issue queue 620 activates control unit 604 signals to manage data-flow and functions in FAU 618 section. A plurality of FAUs 618 may be configured to execute multiple parallel execution (SIMD, single-instruction multiple-data) or a plurality of different instructions (MIMD, multiple-instructions multiple-data) in one cycle. This is possible since the instruction-functionality resides in configuration bits, and different instructions can be pre-programmed to reside within the FAU 618. A FAU issued instructions has to only ensure correct synchronized data flow to the inputs of each FAU. Compute processor 600 includes a configurable data-flow mixer 619 (hereafter called the mixer) that can dynamically route ISA-HWU 608 and FAU 618 output data to any other input-port providing a one cycle feed-through mechanism for data-flow between functional units. This mixer 619 may be dynamically configured by control unit 604 using control signals. Mixer 619 may be a ring connector that traverse input and output ports. The exact functionality of the mixer is described in the incorporated by referenced Provisional Application entitled “Macro-Processor Architectures”. Mixer 619 dynamically concatenates a plurality of FAUs 618 to build larger Macro-Functions that significantly boost performance efficiency. Mixer 619 allows pre-processing ISA-HWU functional unit 608-611 input data using FAU 618 function outputs. Mixer 619 allows post-processing ISA-HWU functional unit 608-611 output data using FAU 618 function inputs. As an example, a significant usefulness of this feature is for a first FAU 618a to decompress incoming compressed data, feed the output of 618a to a second slice 618b to decode incoming encoded data, feed the real data output of 618b to ISA-ALU 608 or ISA-FPU 609 for data-compute. This auto-pipelining is dynamically generated by software tools, described later, independent of Software Application developer intervention. FAUs 618 may receive data from L1-cache 606 and write results back to L1-cache or a scratchpad (not shown) without the need to retire data to L2-cache 613 for access, thereby improving data compute performance. FAU 618 and Mixer 619 may feed-through output data to an adjacent compute cluster via output 621, allowing FAU & Functional-Unit sharing for data compute in multiple clusters. Depending on the position of cluster-to-cluster feed-through required, a latency may be predetermined and managed by the control unit(s) 604. FAU 618 memory 617 may contain a plurality of sets of configuration bit values. A said first set of configuration-bit values may configure a FAU 618a to a first function. A said second set of configuration-bit values may configure the same FAU 618a to a second function. A control signal from control unit 604 may select the first set or the second set of data sets in memory 617 to configure the FAU 618a, thereby providing a control option to dynamically change FAU 618a functionality via control-unit 604. In one embodiment this may take 1-cycle. In another embodiment this may take a few cycles. In yet another embodiment this may take 1000's of cycles, managed by the control unit 604 pre-emptively or during wait-for-interrupt idle time. The reconfigurable latency may depend on the extend and complexity of FAU 618a functionality. Memory 617 may store 128 sets of configuration data sets that define 128 different 8LUT functions, one stored function selected by a 10-bit memory 617 select address code generated by control unit 604 to configure FAU 618 as desired. Mixer 619 may be used to dynamically adjust output-input connectivity to improve content processor 600 functionality through a software mechanism that is discussed next.

A user software application 650 is shown in FIG-6B. The high-level software program comprises pragma-wrappers 651, 652 and 653 identified by the user as FN-pragma's (412 in FIG-4A). The syn-compiler 613 identifies a first group 654, a second group 655, and a third group 656 of a plurality of pragma-wrapper functions that appear in a sequence. Each group may have a different order in which the pragma-wrapper functions appear. First group 654 has the appearance order (651, 652, 653). Second group 655 has the appearance order (653, 651, 652). Third group 656 has the appearance order (652, 653). The syn-compiler may insert a bounding-box 654, 655 and 656 to note that a plurality of FN-macros positioned in FAU 618 are used sequentially. Let us assume that function 651 is programmed into FAU 618a, function 652 is programmed into FAU 618b, and function 653 is programmed into FAU 618c or 618d. During the compilation of bounding-box 654, the compiler may insert a control signal instruction to the mixer 619 to couple FN 651 output to FN 652 input, and FN 652 output to FN 653 input. During compilation of bounding-box 655, the compiler may insert a control signal instruction to the mixer 619 to couple FN 653 output to FN 651 input, and FN 651 output to FN 652 input. During the compilation of bounding-box 655, the compiler may insert a control signal instruction to the mixer 619 to couple FN 652 output to FN 653 input. In this example a sequential pragma-wrapper functions may use a software driven instruction methodology to auto-pipeline input-output connectivity to improve content computing processor 600 performance. Similarly control unit 604 may issue mixer 619 control signals to connect an output to any input. FAU 618a may receive data inputs in a byte-configurable bus (say 8-wires where all 8-wires are selected by a configurable element). FAU 618a may comprise bit-configurable logic elements and segmented routing elements to implement a bit programmable function of the plurality of inputs selected by byte-configured bus. Outputs of 618a may be coupled to a byte-configurable bus. Mixer 619 may couple a plurality of input and output ports, each port capable of handling a bus. Mixer 619 maybe pre-designed to prevent two output ports couple to each other at any time instance to prevent contention and device damage.

A high-level language application software program 650 in FIG-6B comprising: two or more pragma-wrapper functions (651, 652) identified by a user (412 in FIG. 4A) that appear adjacent to each other in a software program, wherein: each of the pragma-wrapper functions 412 is synthesized by a syn-compiler 413 to a gate level netlist 414; and each of the gate-level netlists 414 is placed and routed in a user configurable logic block 618 (in FIG-6A) as hard-macro functions; and the synthesized hard-macros compiled in the syn-compiler 413 to generate instructions for a control unit 604 to issue a control signal to a hardware mixer circuit 619 to dynamically couple an output of the pre-ceding pragma function 651 to an input of the post-ceding pragma function 652. The hardware mixer circuit 619 further comprising a means to couple a plurality of output ports to a plurality of input ports, wherein one or more control signals selectively couple one output port to one input port. The Syn-Compiler further generating a bit pattern 416 (in FIG-4A) of configuration bits to program a said pragma-wrapper function to a said hardware-macro function in a said configurable logic block.

A method of dynamically coupling two consecutive functions in a user application program 650 in FIG-6B, the method comprising: identifying the two functions using pragma-wrappers 412 (in FIG-4A); using a syn-compiler to convert each said pragma-wrapper functions to a configurable FAU 618 in FIG-6A; using the syn-compiler to generate an instruction to enable a hardware mixer circuit 619 to couple pre-ceding pragma-wrapper function output to post-ceding pragma-wrapper function input. In a preferred embodiment, mixer circuit 619 port coupling maybe configured in 1-clock cycle by control signals. The method to enable hardware mixer circuit input-output coupling further comprised of a control signal generated by a control unit 604 from said syn-compiler generated instruction.

Generating control signals to configure Mixer Circuit 619 of FIG-6A is discussed next. During syn-compiler 419 (FIG-4A) step of custom integration layer 452 (FIG-4B) the mixer 619 must be instructed to set up the port connectivity based on FN_Pragma 651-653 (FIG-6B) concatenation identified by bounding-pragmas 654-656. Mixer 619 manages output drivers of one port (out of a plurality of output ports) coupling to an input port (out of a plurality of input ports) without contention between drivers during one-cycle or two-cycle re-configuration. Three output ports configurably coupling to one input port is shown in 800 of FIG-8A. Each port is assumed to be 8-bits (or 8-wide, having 8-wires). A single configurable element 813a output 814a is directed to 8 switches 815a in the output driver bus 816a. Since all 8-wires of the bus, (16-bits, or 32-bits, etc.) couple identically, a single wire coupling is explained below (rather than a bus) for simplicity. It is a byte-configurable bus coupling, and the mixer provides a bus-to-bus coupling between ports by dynamically configuring storage elements located at the port.

Device 800 in FIG-8A shows a “single cycle” dynamically reconfigurable interconnect structure (router) in a Mixer Circuit 619 (FIG-6A). To illustrate control-signal (802a, 802b, 803) configurability in a mixer circuit, 800 shows how 3 output ports 816a-816c may be configurably coupled to an input port 818. The concept is easily expanded to couple many output ports to many input ports. Router 800 comprises an enable signal 803 to gate a clock signal 801 and generate gated-clock signal (gCK) 811 to achieve a single-cycle re-configurability while preventing driver 817a-817c contention during that reconfiguration time. The structure 800 is named a dynamic router. In this example, a plurality of special configuration elements 813 comprised of a latch and two ground connected pass-gates is used. Config element 813 has a set state and a reset state. During the set state, the latch output 814 coupled switch 815 is at an ON=1 state; while in reset state switch 815 is at an OFF=0 state. Either state is programmed into the latch by activating a ground connected pass-gate, only one desired pass-gate activated at any one time. When logic 809 generates an ON signal, the latch enters reset state. When logic 810 is activated, the latch enters set state. When neither 809 or 810 are activated, the latch retains its previously stored state. A control signal 802 comprising a plurality of bits (802a, 802b) is received by a bit-code decoder unit 806, which has 3 decoded outputs 807a, 807b and 807c to program the dynamic router 800. There may be more than 2 decode bits depending on the number of decoded outputs needed for programming configurable elements in 800; N-bits can configure (2N−1) config elements. For two decode-bit values 802a & 802b, the bit-code decoder logic units 804a-804c generate a programming signal for a set-state of a configuration elements 813. Logic blocks 804a-804c provides this single programming signal by correct logic outputs on 807a-807c. As an example, let us say the two bits received on 802a and 802b are A, and B. Logic block 804a-804c outputs are: 807a=NotA*B; 807b=A*NotB; 807c=A*B; and TriState=NotA*NotB, where all 3 signals 807a-807c are at Zero. We can write the decode-bit & decoded-output vector pairs as: (00, 000), (01,100), (10, 010), (11, 001).

The dynamic router 800 comprises 3 output nodes 816a-816c capable of coupling to input node 818, each comprising a driver 817a-817c to transmit a signal at that node. In this example, all 3 output nodes are able to dynamically couple to input node 818 by a programmable means that comprise configuring pass-gate switches 815a-815c ON or OFF. Only one of the three pass-gates switches are active at any time instance. There are 3 configuration bits, or storage elements, 813a-813c to hold the data to configure the 3 switches 815a-815c. The output values of storage bits 813a-813c are written as xyz (x=814a, y=814b, z=814c). There are 4 states of output-input coupling: (i) tri-state 000 when none of the outputs are coupled to input 818; (ii) first-state 100 when output 816a is coupled to input 818; (iii) second-state 010 when output 816b is coupled to input 818, and (iv) third-state 001 when output 816c is coupled to input 818.

Programmable means of configurable storage elements 813a, 813b and 813c comprise an operational sequence to not allow two or more outputs 814a-814c reach logic state 1 simultaneously to prevent driver contention. This is achieved by ensuring a tri-state condition to precede a dynamic reconfiguration within the same re-configuration cycle by the use of an enable signal 803 (issued by a control unit to generate the gated-clock signal 811). All storage elements use the gated-clock signal 811 to facilitate reset and set states of storage. When EN signal 803 is deactivated (i.e. EN=0, signal gCK 811=0), output logic of 809 & 810 decouples storage elements 813 data write paths to retain previously stored data. The feed-back inverters in the latch in 813 retains the data it already has regardless of CLK polarity. When a programming is needed, EN signal 803 must be activated with correct sequencing with CLK cycle. In the shown config element 813: reset is achieved by +ve CLK edge, and EN must precede this edge by a required setup-margin; and set is achieved by −ve CLK edge, and EN must be held past this edge by a required hold-margin. When EN signal 803 is activated (i.e. EN=1), when CLK=1, gCK=1; and when CLK=0, gCK=0. When gCK=1, 809 logic reset ALL configuration elements 813a-813c to outputs 814=0, while logic in 810 disable the set-path of storage elements 813.

Grounded source reset transistors in storage element 813 are sized to write a ZERO at the grounded node. The net result is when EN=1, the first half of gCK=1 cycle will tri-state all the drivers in dynamic router 800. During the second half of gCK=0 cycle, the reset path is disabled by logic in 809, while set path is abled by logic in 810 subject to decoded outputs 807a-807c. At most only one of those signals will have a 1-state, and that will select set-state of one of the bits 813, while the remaining two bits in 813 will hold their reset states. All configuration elements are reconfigured in one-cycle. The programmable means comprises EN signal returning to ZERO state during CLK=0 half of cycle (after hold-margin) after programming the configuration bits, before the next +ve edge of CLK pulse. This is a manageable window of operation. Keeping the EN=1 will force the configuration bits to continuously cycle through reset-state, and set-state every CLK cycle, which is undesirable. The dynamic-router 800 is now reconfigured to operate correctly from the next cycle onwards, until another reconfiguration is initiated. What we described is to dynamically reconfigure a driver connection to a receiver in 1-cycle, so it can be used in the next cycle, without having driver contention during reconfiguration.

A Mixer 619 (FIG-6A) circuit manages connectivity between many input and output ports. A 15-output ports 821 to 15 input ports 825 router 820 is shown in FIG-8B denoted by 1-15 subscripts. In this embodiment, the 15 output-ports 821₁-821₁₅ are configured by a first set of control-signals 827a, and the 15 input ports are configured by a second set of control signals 827b, both using a common enable control signal 831. This enable signal is the same as enable signal 803 of router 800. 822₁-822₁₅ are drivers. 823₁-823₁₅ configured by signals such as 829 & 824₁-824₁₅ configured by signals such as 830 are programmable cross-bar switches. Each port in 821ₖ & 825ₖ (integer k=1 to 15) is shown as an 8-bit port. It can be 16 b, 32 b, or any other depending on the ISA of content computing processor. Control signal 827 is an 8 b bus: the 4 MSB's are used by 826a to configure output ports 821; and 4 LSB's are used by 827b to configure input ports 825. Four signals allow 16 (24) configurable states. An 8-bit instruction-data (generated by syn-compiler 413 in FIG-4A) entered into a control-unit 482 (FIG-4C) register file determines the mixer 619 (FIG-6A) dynamic configuration. Data clocked into this mixer-configure-register (not shown) will determine output-input connectivity of router 820. Four MSB bit control signal values in 827a will setup the 15 signal levels 829 to select one output of 821 to couple into a common bus 828. Using latches 813 prevents the need to constantly setup decoding signals 826a in every clock cycle, saving complexity and power in the router 820. Use of enable signal 831 further allows setting data to mixer-configure-register earlier and clocking the change at exact clock cycle of interest by using enable signal 831. At any one time, two conditions are possible in router-820 connectivity: (1) All ports are tri-stated (no output port is coupled to the bus 828), (2) One output port is coupled to the bus 828. It should be noted that in this method, it is possible for one output port to couple into many input ports if the output driver strengths are adequately designed. Circuit 826a comprise decoding circuits 806, clock gated logic 809, 810, 811, 801, 803 and storage elements 813 shown in 800 of FIG-8A. Circuit 826a receives 4-bit control-signal 827a, setup the decode-logic 805 to program the configuration elements 813 (there are 15=24-1 config bits for 4-bit control signal). When enable 831 is selected, all config bits are reset to “0” state in first-half of clock cycle, and one of the config-bits is set to “1” state in second half of clock cycle, thus avoiding driver contention. The tensor pairs for (control-signal, config-bit) is a (4-bit, 15-bit) pattern. It may be summarized as: (0000, 0000 0000 0000 000), (0001, 1000 0000 0000 000), (0010, 0100 0000 0000 000), (0011, 0010 0000 0000 000), . . . (1111, 0000 0000 0000 001). A single output driver may be coupled to common bus 828 in one clock cycle. Circuit 826b operates identically to circuit 826a. Four LSB bits 827b setup the connectivity of input ports 825. Mixer-config-register setup both Output & Input ports linked in one 8-bit word in the register-file. Common enable signal activates configurability of input ports. That too goes into a tr-state mode in the first half of clock cycle, and configure one input port to couple into common bus 828. Only one common bus 828 is needed for the mixer 619 to facilitate dynamic coupling between 15 input ports and 15 output ports. Decode logic and configuration bit reside at each port. Control signals 831 (1 bit) is at all ports, while 827a (4 bits) is received at output ports, and 827b (4 bits) is received at input ports.

Syn-compiler 413 generates an 8-bit code to determine the mixer connectivity based on the boundary-pragma 654 sequence of FN-pragma's 651, 652, 653. This is a driver specification. Each FN-pragma has a fixed latency determined during timing+PPR step 415 (FIG-4A) in hardware macro creation. Valid output of a FN-pragma is delayed by the latency in clock cycles, and the control-unit is enabled to setup the mixer-config-register as defined by syn-compiler, and use the enable signal 831 to synchronize data flow. This is a dynamic data through-flow technique to auto-pipeline hardware unit executions. Normally in microprocessors, output data of one ISA-HWU must be retired to L2-cache, before another ISA-HWU can access that output data. (There is an exception: some pre-selected ISA-HWU are allowed to write-back output data to D-cache, but that choice is very limited). The use of mixer 619 allows a method to augment content compute HWA by syn-compiler so that the generic ISA-compiler 404 (FIG-4A) is not modified. This is a significant advantage as a content compute processor can work with any ISA infrastructure available in the IC-industry. It can use existing application software programs. The user intervention is limited to FN-Pragma insertion 412 (FIG-4A). Boundary-pragma 654 definition is done by software tools in the integration syn-compiler. Driver instructions capture the mixer and macro-function coupling directives.

A hybrid synthesis and compiler software program 413 (FIG-4A) to generate a content computing hardware module in a silicon, comprising: a user identified high-level function 412 by a pragma-wrapper 412; and a synthesis software program module (within 413) converting the high-level software description of the pragma-wrapper function 412 to a gate level netlist; and a compiler software program module (within 413) identifying a plurality of consecutive pragma-wrapper 412 functions by a boundary-wrapper 654 (FIG-6B), and generating a plurality of register values (an instruction) to direct a programmable mixer-circuit 619 (FIG-6A) to dynamically couple the consecutive pragma-wrapper functions in the order of coupling (654, FIG-6B) in the sequence.

A syn-compiler, comprising: a synthesis software module to convert a software function to a hardware-macro; and a compiler to generate driver directives to couple inputs and outputs to the hardware-macro. The hybrid syn-compiler, wherein the hardware-macro is defined by a gate level netlist generated by the software synthesis module. The hybrid syn-compiler, wherein the software function is configurably enabled as the hardware-macro. The hybrid syn-compiler, wherein a compiler generated driver directive is stored in a register-file of a control unit to generate a control signal. The hybrid syn-compiler, wherein the compiler generated driver directive enables dynamic programming of a plurality of configuration elements to alter the software function input and output coupling.

A hybrid syn-compiler, comprising: a synthesis software module to convert each of a plurality of software functions to a programmable hardware-macro; and a compiler to identify a consecutive sequence of software functions programmed as hardware-macro units, and generate driver instructions to dynamically couple inputs and outputs of the plurality of hardware-macro units in the sequence. The synthesized and compiled application program, wherein a plurality of hardware-macro unit order of appearance in a sequence change, and wherein software compiler module driver directives arrange the new order of the sequence during compile time.

A software syn-compiler program comprising: a software synthesis module; and a software compiler module; wherein, the software synthesis module converts a software function to a programmable hardware-macro comprised of an input and an output; and wherein the software synthesis module generates register values for a control unit to enable programmable hardware-macro unit input coupling and output coupling.

In summary, a software tools flow 700 in FIG-7 to implement content computing in a processor is disclosed. Modules 701, 702, 703, 704, 705, 706 & 707 are analogous to 401, 402, 403, 413, 404, 405 & combined 406-411 in FIG-4A. Software tools flow 700 comprises a syn-compiler module 704 to: synthesize (704a) a software function to a programmable hardware-macro unit; and compile (704b) the hardware-macro unit to define register settings for a control unit to assign the hardware-macro unit input connectivity and output connectivity. A coupled synthesis module 704a and a compile module 704b provides a programmable method to implement content computing in a processor comprising configurable logic.

Although an illustrative embodiment of the present invention, and various modifications thereof, have been described in detail herein with reference to the accompanying drawings, it is to be understood that the invention is not limited to this precise embodiment and the described modifications, and that various changes and further modifications may be effected therein by one skilled in the art without departing from the scope or spirit of the invention as described in this disclosure document.

What is claimed is:

1. A computer processing system (CPS) to execute a user specified content of an application software program, comprising:
a configurable execution unit; and
a software tool that comprises synthesis software and compiler software; and
a method to execute the user specified content as an executable instruction in the configurable execution unit, the method comprised of: identifying the execution unit configuration using the synthesis software, and instantiating the executable instruction using the compiler software.

2. The system of claim 1, wherein the configurable execution unit comprises a plurality of configuration memory elements, and the execution unit configuration includes identifying a bit pattern of the configuration memory elements.

3. The system of claim 1, further comprised of:
a plurality of pre-defined instructions based on an instruction set architecture (ISA); and
a plurality of selectable pre-defined execution units, a said ISA-instruction defining the selection of a said pre-defined execution units;
wherein, an ISA-instruction is executed in ISA-instruction selected execution unit, and the content executable instruction is executed in the configurable execution unit.

4. The system of claim 3, further comprising two or more pipelined stages in an instruction execution pipeline between an instruction fetch stage and an instruction execution unit, the first of said pipelined stages an instruction decode stage, wherein:
an ISA-instruction entering the pipeline moves through said two or more pipelined stages; and
a content executable instruction entering the pipeline moves from decode stage directly to the configurable execution unit.

5. The system of claim 2, wherein the synthesis software further comprising:
a language translation software to generate register-transfer logic (RTL) description of the content in application program; and
a design implementation software that generates a gate-level netlist of the RTL; and
a physical implementation software that combines, position, and route the gate-level netlist in the configurable execution unit, ensure timing performance, and generate the bit-pattern.

6. The system of claim 2, wherein the method to execute the user specified content in the configurable execution unit, further comprising:
reading the bit-pattern from a memory unit, and configuring the configuration memory to implement the user defined function ahead of the content executable instruction in an executable instruction program sequence.

7. The system of claim 6, wherein the bit pattern can be re-configured dynamically during the execution of compiled application program.

8. The system of claim 1, wherein the compiler software further comprising:
an identification generation software to identity a plurality of user specified contents by the identification label.

9. The system of claim 8, wherein the method to execute one of said plurality of user specified contents include the compiler software to instantiate a decodable identification label within the executable instruction.

10. A software tools flow to generate executable instructions in an application software program comprising a combined high level logic synthesis software and language compiler software to:
identify an application software program content that is targeted for hardware implementation as a hardware function in a configurable hardware unit that comprises configuration memory; and
generate a synthesized gate-level netlist of the targeted hardware function; and
generate a bit-stream of configuration memory states to program the targeted hardware function in the configurable hardware unit; and
generate a compiled hardware instruction for a processor unit to execute the instruction in the configured hardware function.

11. The software tools flow of claim 10, wherein identifying an application software program content include inserting a pragma wrapper around a contiguous sequence of application software code.

12. The software tools flow of claim 10, wherein generating a gate-level netlist further comprises:
generating hardware description language (HDL) software code of the identified application software program content; and
generating a gate-level netlist by a physical implementation of the HDL software code; and
generating a layout of said gate-level netlist in the configurable hardware unit.

13. The software tools flow of claim 12, wherein generating the layout in the configurable hardware unit further comprised of identifying configuration memory bit states to:
define a logic gate function in a configurable logic element; and
positioning a plurality of logic gates in a plurality of logic elements to assemble the hardware function; and
interconnecting inputs and outputs of the plurality of logic gates and logic elements to generate the hardware function.

14. The software tools flow of claim 13, wherein the identified configuration bit states define the bit-stream of configuration memory to program the targeted hardware function in the configurable hardware unit.

15. The software tools flow of claim 10, wherein a plurality of identified contents of an application software is executed by a plurality of compiled hardware instructions, each of said hardware instructions generating a unique bit-stream to configure a segment of the configurable execution unit.

16. The software tools flow of claim 10, further comprising an instruction set architecture (ISA) compatible compiler to:
generate an ISA-compatible executable instruction that is executed in a pre-defined execution unit, the pre-defined execution unit said ISA-compatible instruction.

17. A software program for content computing comprised of:
a high-level logic synthesis software to convert an identified content in an application program to a synthesized hardware image; and
a language compiler software to instantiate the content customized instruction to execute in a configurable hardware unit programmed to the synthesized hardware image.

18. The software program of claim 17, further comprised of generating a bit-pattern of a plurality of configuration elements in the configurable hardware to define the hardware image.

19. The software program of claim 17, further comprising a software development kit (SDK) comprising:
a hardware development language software to generate a synthesizable source code from the identified content in an application program, wherefrom the high-level logic synthesis software generates a gate-level netlist using the generated synthesizable source code; and
a physical implementation software to define gate functions, place gates and route the gate-level netlist in the configurable hardware by defining a bit-stream of a plurality of configuration elements in the configurable hardware to generate the hardware image.

20. The software program of claim 17, wherein a plurality of identified contents of an application program are converted to a plurality of hardware images in a configurable hardware unit, and wherein each of said hardware customized instruction includes a unique content identification label.
